(19) United States
(12) Patent Application Publication
(10) Pub. No.: US 2026/0303996 A1
(43) Pub. Date: Oct. 1, 2026

(54) IMAGE SENSOR, OPERATING METHOD THEREOF, AND IMAGING DEVICE INCLUDING IMAGE SENSOR

(71) Applicant: Samsung Electronics Co., Ltd., Suwon-si (KR)

(72) Inventors: Dongjin PARK, Suwon-si (KR); Jeehong LEE, Suwon-si (KR)

(73) Assignee: Samsung Electronics Co., Ltd., Suwon-si (KR)

(21) Appl. No.: 19/409,232

(22) Filed: Dec. 4, 2025

(30) Foreign Application Priority Data
Mar. 25, 2025 (KR) 10-2025-0038159

(51) Int. Cl. H04N 25/77; H04N 25/10; H10F 39/00

(52) U.S. Cl. CPC H04N 25/77; H10F 39/8053; H10F 39/8063; H04N 25/10

(57) ABSTRACT

An image sensor includes a plurality of pixels including a first pixel, a first microlens on the first pixel, and a peripheral circuit configured to drive the first pixel. The first pixel includes a first N² photodiodes in N×N form, and a first N² transfer transistors. P transfer transistors among the first N² transfer transistors are configured to be turned on at time t1 and L transfer transistors among the first N² transfer transistors are configured to be turned on at time t2 different from the time t1. P, N, and L are integers. N is an odd number equal to or greater than 3. P is greater than N²/2. P transfer transistors are included in a first transistor group and L transfer transistors are included in a second transistor group different from the first transistor group.

### CROSS-REFERENCE TO RELATED APPLICATION

This U.S. non-provisional application claims priority under 35 U.S.C. § 119 to Korean Patent Application No. 10-2025-0038159 filed on Mar. 25, 2025, in the Korean Intellectual Property Office, the disclosure of which is incorporated herein by reference in its entirety.

### BACKGROUND

Some example embodiments relate to an image sensor, an operating method thereof, and an imaging device including the image sensor.

An image sensor is a semiconductor-based sensor that receives light and generates an electrical signal, and includes a pixel array having a plurality of pixels. In order to improve the image quality of an external object, the image sensor may support an autofocus (AF) function. Among the autofocus methods, a phase detection autofocus (PDAF) method determines whether a subject is in focus by comparing phase differences of a pair of divided lights that passed through a pair of autofocus pixels. The phase detection autofocus (PDAF) method may allow a camera to focus on an object in a relatively shorter time.

### SUMMARY

Example embodiments of the present disclosure provide an image sensor that performs a phase detection autofocus operation using pixels comprised of an odd number of pixel regions, an operating method thereof, and an imaging device including the image sensor.

An image sensor according some example embodiments of the present disclosure may include a pixel array including a plurality of pixel groups in a first direction and in a second direction, intersecting the first direction, and a peripheral circuit configured to drive the pixel array. Each pixel group of the plurality of pixel groups may include a plurality of pixels in 2M×M form (where M is an even number equal to or greater than 2), and each pixel of the plurality of pixels may include photodiodes in N×N form (where N is an odd number equal to or greater than 3). The peripheral circuit may be configured to obtain, using a first pixel group among the plurality of pixel groups, a first average value of a left image signal corresponding to charges generated in pixel regions of a first group and a second average value of a right image signal corresponding to charges generated in pixel regions of a second group different from the first group, and calculate a disparity for an object based on the first average value and the second average value. The first group may be to the left of the second group in the first direction in the first pixel group, and a number of pixel regions included in the first group and a number of pixel regions included in the second group may be equal to each other.

An operating method of an image sensor according to some example embodiments of the present disclosure may include obtaining a first image signal corresponding to charges generated in pixel regions of a first group, among a plurality of pixel regions disposed in N×N form within one pixel, and a second image signal corresponding to charges generated in pixel regions of a second group different from the first group, generating a left image signal and a right image signal for one pixel group in which pixels are disposed in a 2M×M form using the first image signal and the second image signal, calculating a first average value of the left image signal and a second average value of the right image signal, and calculating a disparity for an object using the first average value and the second average value.

An imaging device according to some example embodiments of the present disclosure may include an optical unit including a lens unit including a plurality of lenses and a lens driver configured to adjust positions of the plurality of lenses, an image sensor configured to focus light passing through the lens unit and convert the light into a digital signal, and output a control signal for adjusting a position of at least one lens of the plurality of lenses of the lens unit, and a processor configured to control the lens driver to adjust the position of the at least one lens of the plurality of lenses based on the control signal. The image sensor may include a pixel array including a plurality of pixel groups in a first direction and a second direction intersecting the first direction, and a peripheral circuit configured to drive the pixel array. Each pixel group of the plurality of pixel groups may include a plurality of pixels in 2M×M form (where M is an even number of 2 or more), and each pixel of the plurality of pixels may include photodiodes in N×N form (where N is an odd number of 3 or more). The peripheral circuit may obtain, in a first pixel group among the plurality of pixel groups, a first average value of a left image signal corresponding to charges generated in pixel regions of a first group and a second average value of a right image signal corresponding to charges generated in pixel regions of a second group different from the first group, and may calculate a disparity for an object based on the first average value and the second average value. The first group may be to the left of the second group in the first direction in the first pixel group, and the number of pixel regions included in the first group and the number of pixel regions included in the second group may be equal to each other.

According to some example embodiments of the present disclosure, a left image signal and a right image signal may be obtained based on pixel signals transmitted from pixels comprised of odd pixel regions, and a phase signal pair may be obtained based on an average value of the left image signal and an average value of the right image signal, and focus may be achieved by calculating disparity for an object based on the phase signal pair. Through this, angles of light incident on the pixel array may be identified with an improved resolution, and an autofocus function may be performed at a relatively higher speed while maintaining a relatively higher resolution.

An image sensor according to some example embodiments of the present disclosure may include a plurality of pixels including at least one first pixel, a first microlens on the at least one first pixel, and a peripheral circuit configured to drive the at least one first pixel, wherein the at least one first pixel comprises a first N² photodiodes in N×N form, and a first N² transfer transistors each connected to corresponding one of the first N² photodiodes, wherein P transfer transistors among the first N² transfer transistors are configured to be turned on at a time t1 and L transfer transistors among the first N² transfer transistors are configured to be turned on at a time t2 different from the time t1, wherein P, N, and L are integers, wherein N is an odd number equal to or greater than 3, wherein P is greater than N²/2, wherein L is equal to or greater than 2, wherein P is different from L, and wherein the P transfer transistors are included in a first transistor group and the L transfer transistors are included in a second transistor group different from the first transistor group.

An image sensor according to some example embodiments of the present disclosure may include a plurality of pixels including a first pixel, a first microlens on the first pixel, and a peripheral circuit configured to drive the first pixel, wherein the first pixel comprises N² photodiodes in NxN form and N² transfer transistors each connected to corresponding one of the N² photodiodes, wherein P transfer transistors among the N² transfer transistors are configured to be turned on at a time t1 and L transfer transistors among the N² transfer transistors are configured to be turned on at a time t2 different from the time t1, wherein P, N, and L are integers, wherein N is an odd number equal to or greater than 3, wherein P is different from L, wherein the P transfer transistors are included in a first transistor group and the L transfer transistors are included in a second transistor group different from the first transistor group, and wherein the peripheral circuit is configured to generate a first signal by turning on the P transfer transistors based on P photodiodes included in the first pixel and generate a second signal by turning on the L transfer transistors based on P+L photodiodes included in the first pixel.

An image sensor according to some example embodiments of the present disclosure may include a plurality of pixels including a first pixel, a first microlens on the first pixel, and peripheral circuit configured to drive the first pixel, wherein the first pixel comprises N² photodiodes in N×N form and N² transfer transistors each connected to corresponding one of the N² photodiodes, wherein P transfer transistors among the N² transfer transistors are configured to be turned on at a time t1 and L transfer transistors among the N² transfer transistors are configured to be turned on at a time t2 different from the time t1, wherein P, N, and L are integers, wherein N is an odd number equal to or greater than 3, wherein P is equal to or greater than 2L, wherein the P transfer transistors are included in a first transistor group and the L transfer transistors are included in a second transistor group different from the first transistor group, and wherein the peripheral circuit is configured to generate a first signal by turning on the P transfer transistors based on P photodiodes included in the first pixel and generate a second signal by turning on the L transfer transistors based on P+L photodiodes included in the first pixel.

Advantages and effects of the example embodiments are not limited to the foregoing content and may be more easily understood in the process of describing example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram of an imaging device according to some example embodiments of the present disclosure.

FIG. 2 is a block diagram simply illustrating an image sensor according to some example embodiments of the present disclosure.

FIG. 3 is a plan view simply illustrating a pixel arrangement of a pixel array according to some example embodiments of the present disclosure.

FIG. 4 and FIG. 5 are plan views of a structure of a pixel group according to some example embodiments of the present disclosure.

FIG. 6 is an example circuit diagram of a pixel of an image sensor according to some example embodiments of the present disclosure.

FIG. 7 is a timing diagram of a readout operation of a pixel according to some example embodiments of the present disclosure.

FIGS. 8A, 8B, and 8C are views illustrating a movement of charges in a readout operation according to some example embodiments of the present disclosure.

FIGS. 9A, 9B, and 9C and FIGS. 10A, 10B, and 10C are plan views of an image signal according to some example embodiments of the present disclosure.

FIGS. 11, 12, and 13 are flowcharts of an operation of an image sensor according to some example embodiments of the present disclosure.

FIGS. 14A and 14B are timing diagrams of a readout operation of a pixel according to some example embodiments of the present disclosure.

FIGS. 15A, 15B, 15C, and 15D are views illustrating a movement of charges in a readout operation according to some example embodiments of the present disclosure.

FIGS. 16A and 16B are plan views of an image signal according to some example embodiments of the present disclosure.

FIGS. 17 and 18 are flow charts of an operation of an image sensor according to some example embodiments of the present disclosure.

FIG. 19 is an example circuit diagram of a pixel of an image sensor according to some example embodiments of the present disclosure.

FIG. 20 is a timing diagram of a readout operation of a sub-pixel group according to some example embodiments of the present disclosure.

FIGS. 21A and 21B are plan views of an image signal according to some example embodiments of the present disclosure.

FIGS. 22, 23, and 24 are flow charts of an operation of an image sensor according to some example embodiments of the present disclosure.

FIGS. 25, 26A, and 26B are plan views of a structure of a pixel group according to some example embodiments of the present disclosure.

FIGS. 27A, 27B, 27C, and 27D are plan views of an operation of a pixel group according to some example embodiments of the present disclosure.

FIG. 28 is a plan view of a structure of a pixel group according to some example embodiments of the present disclosure.

FIGS. 29A, 29B, 29C, and 29D are plan views of an operation of a pixel group according to some example embodiments of the present disclosure.

FIG. 30 is a plan view of a structure of a pixel group according to some example embodiments of the present disclosure.

FIGS. 31A, 31B, 31C, and 31D are plan views of an operation of a pixel group according to some example embodiments of the present disclosure.

FIGS. 32 and 33 are plan views of a structure of a pixel group according to some example embodiments of the present disclosure.

FIG. 34 is a block diagram illustrating a charge device including an imaging device according to some example embodiments of the present disclosure.

### DETAILED DESCRIPTION OF EXAMPLE EMBODIMENTS

Hereinafter, example embodiments of the present disclosure will be described with reference to the accompanying drawings.

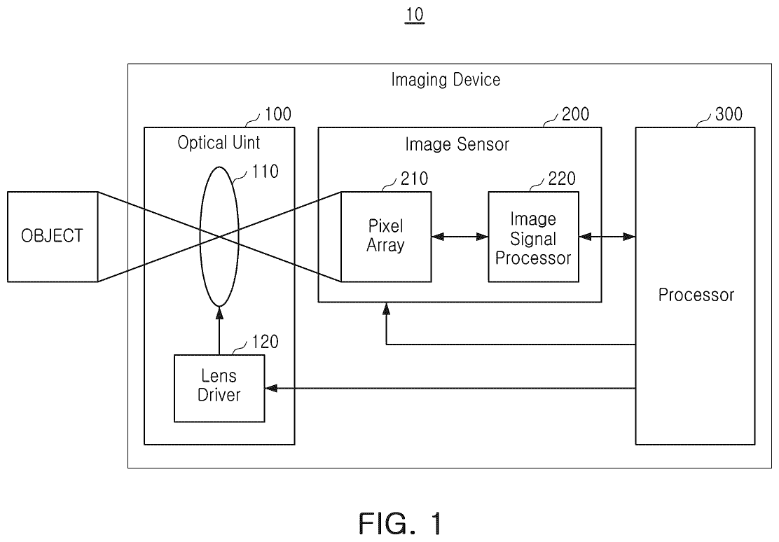

FIG. 1 is a block diagram of an imaging device according to some example embodiments of the present disclosure.

Referring to FIG. 1, an imaging device 10 according to some example embodiments of the present disclosure may include an optical unit 100, an image sensor 200, and a processor 300. The imaging device 10 may have an autofocus (AF) function.

The optical unit 100 may be a component configured to receive light, and is an optical light collection device using a mirror and a lens. For example, the optical unit 100 may change a path of light reflected by an object using optical characteristics such as light dispersion or refraction. The optical unit 100 may include a lens unit 110, and a lens driver 120. The optical unit 100 may further include a mirror, an aperture, and an aperture driver. The lens unit 110 may be comprised of a plurality (or a system) of lenses.

The lens driver 120 may receive information about focus detection from the processor 300, and may adjust a position of at least one of the lenses included in the lens unit 110 according to a control signal (or adjustment signal) provided from the processor 300. For example, the lens driver 120 may move the lens in a direction in which a distance from the object increases or decreases. Depending on the operation of the lens unit 110, the object may be focused or blurred, and when there are a plurality of objects, the object that is focused may vary.

The image sensor 200 may be a Complementary Metal Oxide Semiconductor (CMOS) Image Sensor (CIS) that converts an optical signal into an electrical signal. The image sensor 200 may convert incident light into image data. The image sensor 200 may include a pixel array 210 and an image signal processor 220. An optical signal corresponding to the light transmitted through the lens unit 110 may reach a light-receiving surface of the pixel array 210 and may form an image of an object.

The pixel array 210 may include a plurality of pixels arranged in a matrix, and each of the plurality of pixels may include at least one photoelectric conversion element. A microlens, a color filter, and the like, may be disposed in a path through which an optical signal is incident on the photoelectric conversion element.

The image signal processor 220 may process a plurality of items of raw data output from the pixel array 210 to generate image data. The image data may be generated in frame units. The image signal processor 220 may perform image post-processing operations such as digital binning, noise reduction processing, gain adjustment, waveform standardization processing, interpolation processing, white balance processing, gamma processing, and edge enhancement processing on the raw data. In some example embodiments, the image signal processor 220 may generate a control signal for adjusting a focus of the imaging device 10.

In some example embodiments, the image signal processor 220 may obtain a position of focus, a direction of focus, and/or a distance between the object and the image sensor 200 by performing phase difference arithmetic operations based on a phase signal pair obtained from one pixel or two or more adjacent pixels. The image data and control signals obtained by the image signal processor 220 may be provided to the processor 300. According to some example embodiments, the image signal processor 220 may include the phase signal pair in the image data and may directly provide the image data to the processor 300.

The processor 300 may control operations of each component of the imaging device 10 and may provide a control signal therefor. The processor 300 may receive the image data and the control signals (e.g., control signal CTRL) from the image signal processor 220. The processor 300 may store the image data in an external memory or display the image data on a display device, or the like. According to some example embodiments, the processor 300 may perform additional image post-processing operations, such as adjusting image parameters such as brightness, contrast, and luminance for the image data. The processor 300 may adjust the focus on the object, such as controlling the lens driver 120 so that the lens driver 120 moves the position of the lens unit 110 based on the control signal CTRL received from the image signal processor 220. According to some example embodiments, the processor 300 may receive the phase signal pair from the image signal processor 220, may perform a phase difference arithmetic operation, and may adjust the focus on the object OBJECT based on the result thereof.

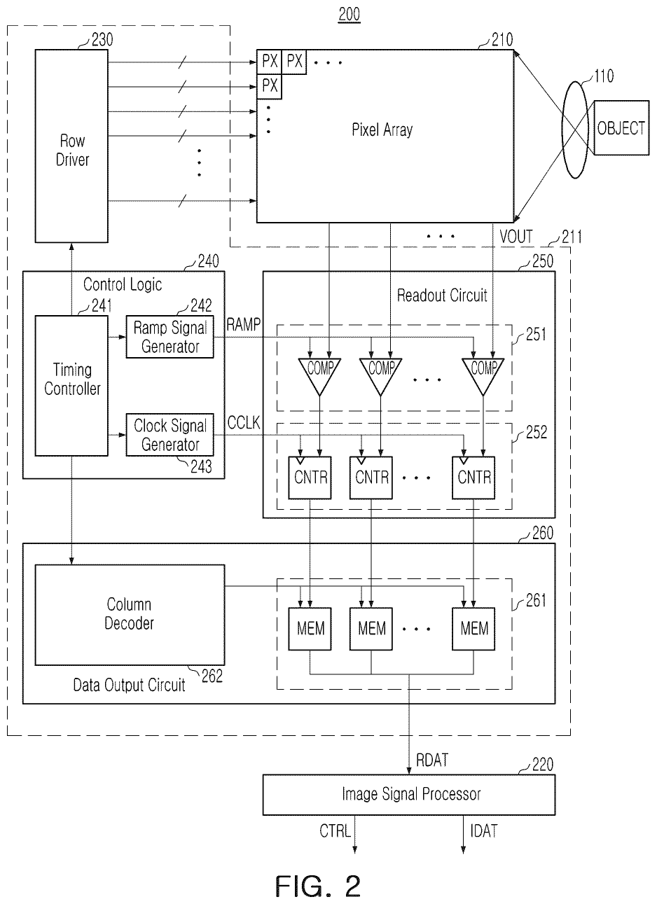

FIG. 2 is a block diagram illustrating an image sensor according to some example embodiments of the present disclosure.

Referring to FIG. 2, the image sensor 200 according to some example embodiments of the present disclosure may include a pixel array 210, a peripheral circuit 211, and an image signal processor 220. The peripheral circuit 211 may include a row driver 230, a control logic 240, a readout circuit 250, and a data output circuit 260.

The image sensor 200 may convert an optical signal of an object incident through the lens unit 110 into an electrical signal, and may obtain image data IDAT based on the converted electrical signals.

The pixel array 210 may include a plurality of row lines, a plurality of column lines, and a plurality of pixels PX connected to the plurality of row lines and the column lines and arranged in a matrix. The row lines may extend in a first direction, and a control signal output from the row driver 230 to a device provided in the pixel PX, for example, a transistor, may be transmitted through the row lines. The column lines may extend in a second direction, intersecting (e.g., perpendicular to) the first direction, and may be connected to pixels PX arranged along the second direction. A pixel signal VOUT output from the pixels PX may be transmitted to the readout circuit 250 through the column line.

Each pixel PX may include at least one photoelectric conversion element. The photoelectric conversion element may generate an electric signal in response to incident light. For example, the photoelectric conversion element may include a photodiode, a phototransistor, a photogate, or a pinned photodiode. For convenience of explanation, the structure of the pixel PX is described below assuming that the photoelectric conversion element is a photodiode, but the present disclosure is not limited thereto.

The pixel PX may convert charges generated by the photoelectric conversion element in response to light into an electric signal and may output the electric signal. The pixel signal VOUT, which is an electric signal output from the pixel PX, may be transmitted to the readout circuit 250 through the column line.

A microlens and a color filter may be disposed in a path through which light is incident on the pixel PX. The color filter may transmit light of a specific color, for example, a wavelength of a specific color region, among the light incident through the microlens, and may determine the color that may be detected by the photoelectric conversion element of the pixel PX depending on the color filter provided in the pixel PX.

In some example embodiments, each of the plurality of pixels PX may be classified into one of a red pixel, a green pixel and a blue pixel depending on the color of the color filter. However, the type of the pixel PX according to some example embodiments of the present disclosure is not limited thereto. For example, the plurality of pixels PX may further include a cyan pixel, a yellow pixel, and/or a magenta pixel.

The row driver 230 may generate a control signal for driving the pixel array 210 in response to the control of the control logic 240, and may provide the control signal to the plurality of pixels PX of the pixel array 210 through the plurality of row lines. In some example embodiments, the row driver 230 may control the pixels PX to detect incident light in units of row lines by providing a transfer signal. In some example embodiments, the row driver 230 may output a transfer signal, a selection signal, a reset signal, and the like, through the row line.

The control logic 240 may be implemented as a processing circuit such as hardware including a logic circuit, or may be implemented as a combination of hardware and software such as a processor executing software that performs a compression operation. The control logic 240 may include a timing controller 241, a ramp signal generator 242, and a clock signal generator 243.

The timing controller 241 may generate a control signal to control the operation timing of each component included in the image sensor 200. For example, the timing controller 241 may provide a row control signal to the row driver 230, and may allow the row driver 230 to drive a plurality of pixels PX in units of row lines in response to the row control signal. As another example, the timing controller 241 may provide a ramp control signal to the ramp signal generator 242 to control a ramp signal RAMP, and the ramp signal generator 242 may generate the ramp signal RAMP for the operation of a comparison circuit 251 in response to the ramp control signal.

The ramp signal generator 242 may provide the ramp signal RAMP having a predetermined (or given or desired) inclination and gradually increasing or decreasing to the readout circuit 250. For example, the ramp signal RAMP may have a waveform that maintains a constant voltage, decreases at a determined inclination, and then returns to a constant voltage.

The clock signal generator 243 may provide a counting clock signal CCLK to a counter circuit 252. The acquisition timing and frequency of the counting clock signal CCLK may be controlled by the timing controller 241. For example, the clock signal generator 243 may be implemented as a gray code generator that obtains a gray code, which is a binary code in which code values sequentially increase. The clock signal generator 243 may generate a plurality of code values having a resolution according to a set number of bits as a counting clock signal CCLK.

The readout circuit 250 may read an analog pixel signal output by pixels PX connected to a selected row line, among a plurality of pixels PX, under the control of the control logic 240, and may convert the pixel signal into a digital counting signal. The counting signal may have a count value of counting clock signal CCLK corresponding to the intensity of the pixel signal. The readout circuit 250 may include a comparison circuit 251 and a counter circuit 252.

The comparison circuit 251 may include a plurality of comparators COMP. In some example embodiments, the comparators COMP may be implemented with one or more amplifiers, for example, an operational transconductance amplifier (OTA). Each of the comparators COMP may compare a reset voltage and a signal voltage output through the connected column line, for example, voltages of each pixel signal VOUT, with a voltage of the ramp signal RAMP.

The counter circuit 252 may include a plurality of counters CNTR. Each counter CNTR may count a comparison signal output from a corresponding comparator COMP, based on the counting clock signal CCLK obtained from a clock signal generator 243.

The data output circuit 260 may temporarily store a counting signal output from the readout circuit 250, amplify the counting signal and output the counting signal as raw data RDAT. The data output circuit 260 may include a column decoder 262 and a buffer circuit 261.

The buffer circuit 261 may include a plurality of memories MEM. The plurality of memories MEM may temporarily store a counting signal output from a corresponding counter CNTR. The buffer circuit 261 may output the counting signal as raw data RDAT by a control signal received from the column decoder 262. In some example embodiments, the raw data RDAT may include information on a color of an object and information on a phase of the object. According to some example embodiments, the raw data may include a reset image signal, a first image signal, a second image signal, a sum image signal, or a column image signal.

The column decoder 262 may control the output timing of counting signals stored in a plurality of memories MEM according to the control of the timing controller 241. For example, the plurality of memories MEM may sequentially output counting signals according to the control of the column decoder 262. According to some example embodiments, the raw data RDAT may be output to the image signal processor 220 or may be output to the outside of the image sensor 200.

The image signal processor 220 may perform various signal processing on the raw data RDAT received from the data output circuit 260. The image signal processor 220 may obtain (or calculate) a phase signal pair based on information on the phase of the object included in the raw data RDAT. According to some example embodiments, the image signal processor 220 may be arranged in an external processor (for example, processor 300) or may be arranged inside the control logic 240.

In some example embodiments, the image sensor 200 may support an autofocus (AF) function, and may perform the autofocus function in a phase detection autofocus (PDAF) manner. The PDAF may be a method of calculating a disparity between phases of images formed on the image sensor 200 and focusing on the object. Here, the disparity may mean a difference in coordinates between left and right image data obtained for the object being imaged.

For example, the processor 300 may calculate the disparity for the object by performing a phase difference arithmetic operation based on a plurality of phase signal pairs obtained from the image signal processor 220. The processor 300 may generate the control signal (or adjustment signal) for adjusting focus based on the calculated disparity and provide the control signal (or adjustment signal) to the lens driver 120. The lens driver 120 may adjust a position of at least one of the lenses included in the lens unit 110 based on the control signal (or adjustment signal). According to some example embodiments, the image signal processor 220 may include a phase signal pair in the image data IDAT and may transmit the phase signal pair to the processor 300. Alternatively, a phase difference arithmetic operation for the phase signal pair and adjustment of the lens unit 110 based thereon may be executed in the image signal processor 220.

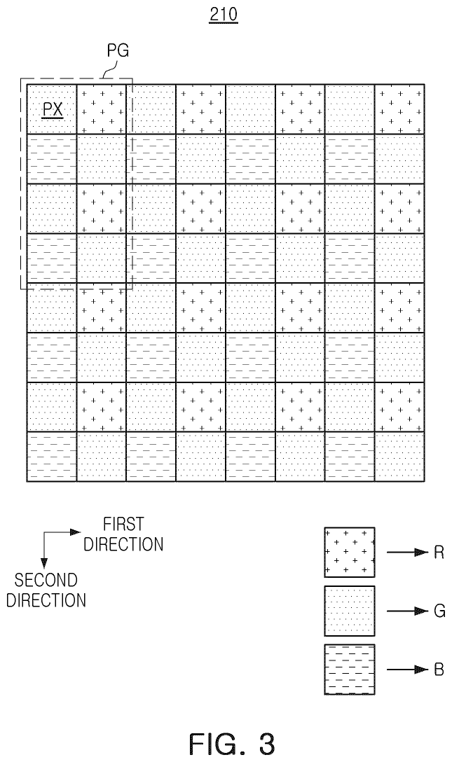

FIG. 3 is a plan view illustrating a pixel arrangement of the pixel array 210 according to some example embodiments of the present disclosure.

Referring to FIG. 3, the pixel array 210 according to some example embodiments of the present disclosure may include a plurality of pixels PX. For example, the plurality of pixels PX may include a plurality of red pixels (R), green pixels (G), and blue pixels (B). In the pixel array 210, a plurality of pixel groups PG may be repeatedly arranged according to a certain (or given or desired) pattern. The number of pixels PX included in the pixel array 210 may be determined according to the resolution of the pixel array 210.

In some example embodiments, a plurality of pixels PX included in each of the plurality of pixel groups PG may be arranged in 2M×M form (or arrangement) (where M is a natural number equal to or greater than 2), and the plurality of pixels PX may be arranged in a Bayer pattern. For example, in some example embodiments illustrated in FIG. 3, eight pixels PX may be arranged in a 4×2 form (or arrangement) in each of the plurality of pixel groups PG. In the following disclosure, for convenience of explanation, it is assumed that each of the plurality of pixel groups PG is comprised of eight pixels PX arranged in a 4×2 form (or arrangement), but the arrangement of the pixels PX is not limited thereto.

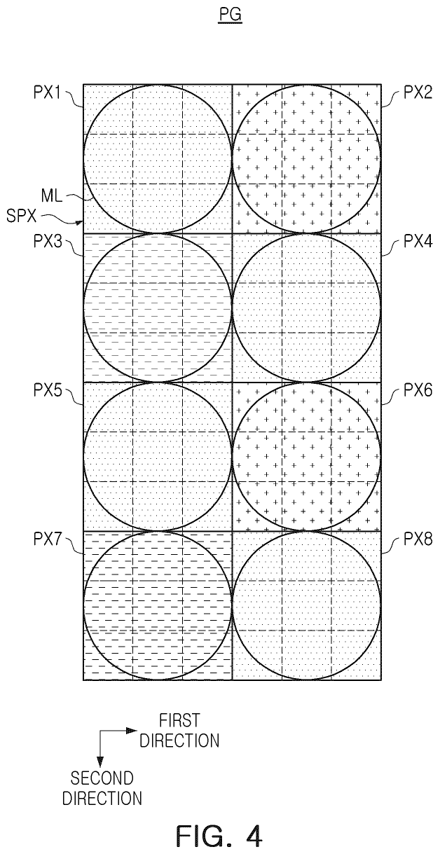

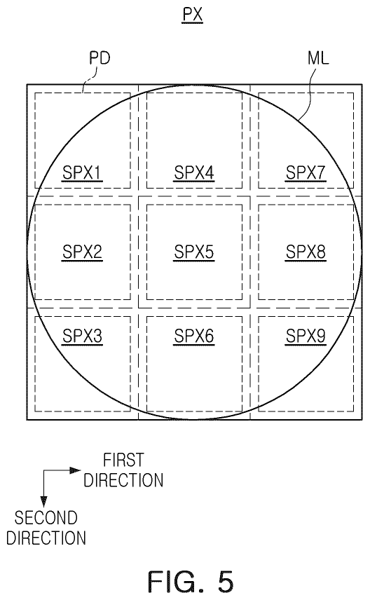

FIG. 4 and FIG. 5 are plan views of the structure of a pixel group according to some example embodiments of the present disclosure. FIG. 5 is an enlarged view of one of the pixels PX1 to PX8 included in the pixel group PG illustrated in FIG. 4.

Referring to FIG. 4, the pixel group PG according to some example embodiments of the present disclosure may include eight pixels PX1 to PX8 arranged in a 4×2 form. Each of the pixels PX1 to PX8 may include one microlens ML and a plurality of pixel regions SPX arranged in N×N form (where N is an odd number equal to or greater than 3). A photodiode may be disposed in each of the plurality of pixel regions SPX, and thus, the number of photodiodes included in each of the pixels PX1 to PX8 may be equal to or greater than the number of the plurality of pixel regions SPX. In some example embodiments, each of the pixels PX1 to PX8 may include a N² photodiodes arranged in N×N form.

In some example embodiments illustrated in FIG. 4, it is assumed that each of the pixels PX1 to PX8 includes a plurality of pixel regions SPX arranged in a 3×3 form, but the present disclosure is not limited thereto. In the following, for convenience of explanation, it is assumed that each of the pixels PX1 to PX8 includes a plurality of pixel regions SPX arranged in a 3×3 form and each of the pixel regions SPX in one pixel shares one microlens ML, and the description will be made in more detail, but the configuration of the pixels PX1 to PX8 and the pixel regions SPX is not limited thereto. For example, each of the pixels PX1 to PX8 may include a plurality of pixel regions arranged in a 5×5 form or a 7×7 form.

Referring to FIG. 5, one pixel PX may include a plurality of pixel regions SPX1 to SPX9 arranged in a 3×3 form, and the plurality of pixel regions SPX1 to SPX9 may share one microlens ML. Each of the pixel regions SPX1 to SPX9 may include a photodiode PD. The pixel regions SPX1 to SPX9 included in one pixel PX may share at least one or more floating diffusion regions.

In some example embodiments, pixel regions SPX1 to SPX9 included in a pixel PX may share one floating diffusion region. In this case, outputs of pixel regions SPX1 to SPX9 included in one pixel PX may be output through one column line. In some example embodiments, each of pixel regions SPX1 to SPX3, SPX4 to SPX6 and SPX7 to SPX9 arranged in the same position in the first direction and arranged along the second direction, in one pixel PX, may form a sub-pixel group sharing one floating diffusion region. In this case, pixel signals generated by charges generated by three photodiodes included in each sub-pixel group may be output through one column line.

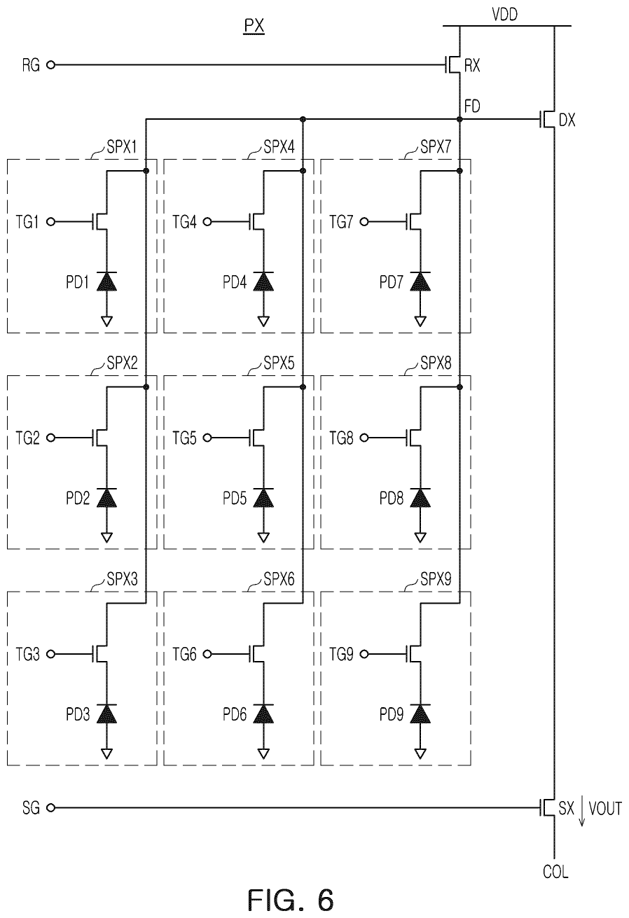

FIG. 6 is an example circuit diagram of a pixel of an image sensor according to some example embodiments of the present disclosure.

Referring to FIG. 6, a plurality of pixel regions SPX1 to SPX9 included in a pixel PX according to some example embodiments of the present disclosure may share a single floating diffusion region FD. A single pixel PX may further include a N² photodiodes PD1 to PD9, a N² transfer transistors, a reset transistor RX, a driving transistor DX, and a selection transistor SEL. The pixel PX may be provided with power supply voltage VPIX. The power supply voltage VPIX may be connected to the one of the terminals (e.g., drain terminal) of the reset transistor RX and the driving transistor DX. Each of the plurality of pixel regions SPX1 to SPX9 included in the single pixel PX may be defined as including a single photodiode (PD1, PD2, . . . or PD9) and a single transfer gate that receives a corresponding transfer signal (e.g., transfer signals TG1, TG2, . . . or TG9). For example, each of the first to nineth transfer gates (also, referred to as transfer transistors) may be a transistor connected to the corresponding first to nineth photodiode PD1 to PD9 and receiving the corresponding first to nineth transfer signal TG1 to TG9. According to some example embodiments, the number of at least one of the reset transistor RX, the driving transistor DX, and the selection transistor SX included in the single pixel PX may be two or more.

The reset transistor RX may be turned on by a reset signal RG to remove charges from the floating diffusion region FD. The floating diffusion region FD may be accumulated by moving charges obtained from at least one of the photodiodes PD1 to PD9. The driving transistor DX may amplify a voltage determined by the charges accumulated in the floating diffusion region FD to generate a pixel signal VOUT. The selection transistor SX may be driven by a selection signal SG to output the pixel signal VOUT to a readout circuit through a column line COL.

The N² transfer transistors may be turned on by corresponding transfer signals TG1 to TG9 to transmit the charges obtained by the photodiodes PD1 to PD9 to the floating diffusion region FD. For example, while a first transfer transistor is turned on by a first transfer signal TG1 received from the row driver 230, the charges obtained from a first photodiode PD1 may be accumulated by moving to the floating diffusion region FD. The second to ninth transfer transistors also may operate in a similar manner, so that the charges obtained from the corresponding photodiodes PD2 to PD9 may move and may be accumulated in the floating diffusion region FD.

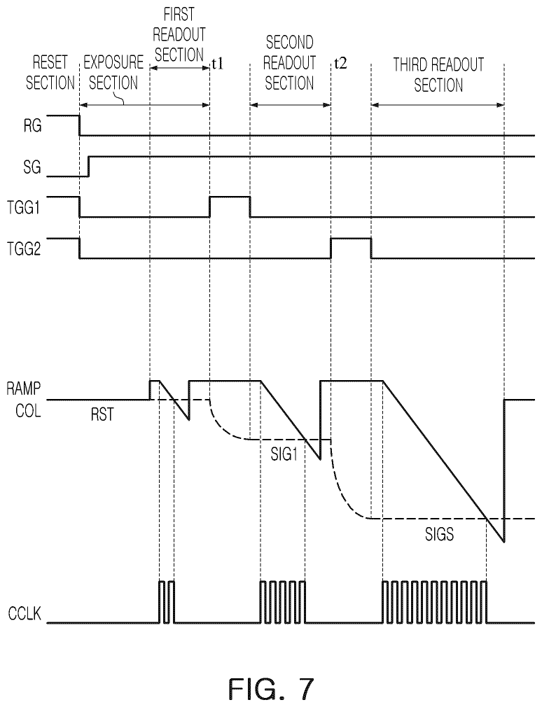

FIG. 7 is a timing diagram of a readout operation of a pixel according to some example embodiments of the present disclosure. FIG. 7 is a timing diagram for the readout operation of the pixel PX described with reference to FIG. 6.

A reset level of the pixel may differ from each device due to a difference in a process or depending on the time at which the reset operation is performed. Accordingly, each pixel may first output a reset voltage RST and then output signal voltages SIG1 and SIGS. The pixel signal may be determined by a difference between the reset voltage RST and the signal voltages SIG1 and SIGS. For example, by subtracting a result of counting the time at which the ramp voltage RAMP is greater than the reset voltage RST, from a result of counting the time at which the ramp voltage RAMP is greater than the signal voltages SIG1 and SIGS, a pixel signal may be determined. In this manner, the pixel signal may be generated due to the difference between the reset voltage RST and the signal voltages SIG1 and SIGS, thereby reducing a signal deviation between the pixel signals output from a plurality of pixels.

Referring to FIG. 7, an image sensor according to some example embodiments of the present disclosure may read pixel signals based on a Reset-Signal-Signal (RSS) readout method. For example, the image sensor may output a first image signal based on a difference between the result of counting the reset voltage RST and the result of counting the first signal voltage SIG1, and may output a sum image signal based on a difference between the result of counting the reset voltage RST and the result of counting the sum signal voltage SIGS.

The ramp signal RAMP may be a signal generated by a ramp signal generator and provided to a comparator in a readout circuit while a readout operation is performed. A waveform of the ramp signal RAMP may be determined according to the type of the pixel signal VOUT output from the pixel array while the readout operation is performed. A level of the ramp signal RAMP may decrease at a predetermined inclination, and when the level of the ramp signal RAMP is lower than a level of the pixel signal VOUT, a level of the comparison signal may transition. A comparator connected to a column line may compare the ramp signal RAMP and the pixel signal VOUT, and may output a comparison result as a comparison signal.

The comparison signal output from the comparator may be transmitted to a counter. The counter may count the comparison signal based on a counting clock signal CCLK. In some example embodiments, the counter may count the number of counting clock signals CCLK from a point at which the level of the ramp signal RAMP decreases to a point at which the level of the comparison signal transitions, for example, a point at which the level of the ramp signal RAMP becomes equal to the level of the pixel signal.

Referring to FIGS. 6 and 7 together, a reset operation in which the reset transistor RX and the N² transfer transistors are turned on to remove charges from the floating diffusion region FD and the N² photodiodes PD1 to PD9 may be performed. Then, the reset transistor RX and the N² transfer transistors may be turned off to start an exposure section. During the exposure section, the pixel PX may be exposed to light. Charges may be generated in the photodiodes PD1 to PD9 included in the pixel PX by the incident light. The pixel PX may output the reset voltage RST of the floating diffusion region FD to the column line COL.

In a first readout section, the comparator may compare the reset voltage RST output by the pixel PX to the column line COL with a voltage of the ramp signal RAMP. In some example embodiments illustrated in FIG. 7, the counter may count the time at which the reset voltage RST is lower than the voltage of the ramp signal RAMP. A reset count value obtained by counting the reset voltage RST may be stored in a memory of a latch or a buffer circuit inside the counter.

Prior to a second readout operation, a first transfer signal group TGG1 may be transitioned to a voltage corresponding to logic high. The first transfer signal group TGG1 may include transfer signals input to P transfer transistors (wherein P is greater than N²/2) included in some of the plurality of pixel regions SPX1 to SPX9. For example, the first transfer signal group TGG1 may include the first to third transfer signals TG1 to TG3, or the first to sixth transfer signals TG1 to TG6. Alternatively, the first transfer signal group TGG1 may include the seventh to ninth transfer signals TG7 to TG9, or the fourth to ninth transfer signals TG4 to TG9.

The P transfer transistors may be turned on (e.g., at the time t1) by the transfer signals included in the first transfer signal group TGG1, so that the charges of the photodiodes connected to the turned-on transfer transistors may move to the floating diffusion region FD. The pixel PX may output the first signal voltage SIG1 corresponding to the charges accumulated in the floating diffusion region FD to the column line COL.

In a second readout section, the comparator may compare the first signal voltage SIG1 output by the pixel PX to the column line COL with the voltage of the ramp signal RAMP. In some example embodiments illustrated in FIG. 7, the counter may count the time during which the first signal voltage SIG1 is lower than the voltage of the ramp signal RAMP. A first count value obtained by counting the first signal voltage SIG1 may be stored in a memory of a latch or a buffer circuit within the counter.

Prior to a third readout, a second transfer signal group TGG2 may transition to a voltage corresponding to logic high. The second transfer signal group TGG2 may include the remaining transfer signals not included in the first transfer signal group TGG1, among the transfer signals TG1 to TG9. For example, when the first transfer signal groups TGG1 are the first to third transfer signals TG1 to TG3, the second transfer signal groups TGG2 may be the fourth to ninth transfer signals TG4 to TG9. As another example, when the first transfer signal groups TGG1 are the first to sixth transfer signals TG1 to TG6, the second transfer signal groups TGG2 may be the seventh to ninth transfer signals TG7 to TG9. As another example, when the first transfer signal groups TGG1 are the seventh to ninth transfer signals TG7 to TG9, the second transfer signal groups TGG2 may be the first to sixth transfer signals TG1 to TG6. In another example, when the first transfer signal groups TGG1 are the fourth to ninth transfer signals TG4 to TG9, the second transfer signal group TGG2 may be the first to third transfer signals TG1 to TG3.

The L transfer transistors (wherein L is equal to or greater than 2) may be turned on (e.g., at the time t2) by the transfer signals included in the second transfer signal group TGG2, so that the charges of the photodiodes connected to the turned-on transfer transistors may move to the floating diffusion region FD. In some example embodiment, sum of L and P may be N². In some example embodiments, the L transfer transistors may be the transfer transistors other than P transfer transistors among the N² transfer transistors. The pixel PX may output the sum signal voltage SIGS corresponding to the charges accumulated in the floating diffusion region FD to the column line COL.

In the third readout section, the comparator may compare the sum signal voltage SIGS output by the pixel PX to the column line COL with the voltage of the ramp signal RAMP. In some example embodiments illustrated in FIG. 7, the counter may count the time at which the sum signal voltage SIGS is lower than the voltage of the ramp signal RAMP. The sum count value that is the count value of the sum signal voltage SIGS may be stored in the memory of a latch or a buffer circuit inside the counter.

In some example embodiments, the first pixel signal SIG1 may be obtained from some of the entire pixel regions, and the sum pixel signal SIGS may be obtained from the entire pixel regions, so that a signal range of the sum pixel signal SIGS may be wider than a signal range of the first pixel signal SIG1. In some example embodiments, a range of a code value provided as the counting clock CCLK in the third readout section, for example, the number of clocks toggled, may be wider than the range of the code value provided in the second readout section.

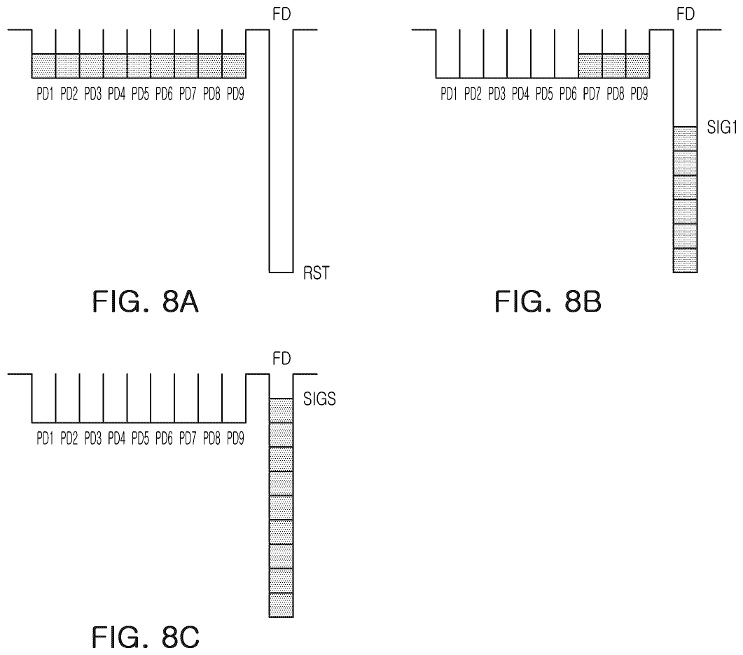

FIGS. 8A to 8C are views illustrating a movement of charges in a readout operation according to some example embodiments of the present disclosure. FIGS. 8A to 8C schematically illustrate energy levels of a floating diffusion region and a plurality of photodiodes included in one pixel. FIGS. 8A to 8C may correspond to energy levels of a pixel in a first readout operation, a second readout operation and a third readout operation, among the readout operations of the pixel PX described with reference to FIG. 7 above, respectively. For convenience of explanation, in some example embodiments illustrated in FIGS. 8A to 8C, it is assumed that the first transfer signal group includes the first to sixth transfer signals, but the present disclosure is not limited thereto.

Referring to FIG. 8A, during an exposure section, each of the N² photodiodes PD1 to PD9 may generate charges in response to light. During the exposure section, the floating diffusion region FD may be in a reset state, and may thus have a potential corresponding to a reset voltage RST. During the first readout section, the pixel may output the reset voltage RST corresponding to a potential of the floating diffusion region FD.

Referring to FIG. 8B, prior to the second readout section, the P transfer transistors may be turned on by the first to sixth transfer signals included in the first transfer signal group. Accordingly, the charges generated by the first to sixth photodiodes PD1 to PD6 may move to the floating diffusion region FD. The floating diffusion region FD may have a potential corresponding to the first signal voltage SIG1. During the second readout section, the pixel may output the first signal voltage SIG1 corresponding to the potential of the floating diffusion region FD.

Referring to FIG. 8C, prior the third readout section, the L transfer transistors may be turned on by the seventh to ninth transfer signals included in the second transfer signal group different from the first transfer signal group. Accordingly, the charges generated in the seventh to ninth photodiodes PD7 to PD9 may move to the floating diffusion region FD. Referring to FIG. 8C, before the third readout section starts, the charges generated in the N² photodiodes PD1 to PD9 may be accumulated in the floating diffusion region FD. The floating diffusion region FD may have a potential corresponding to the sum signal voltage SIGS. During the third readout section, the pixel may output the sum signal voltage SIGS corresponding to the potential of the floating diffusion region FD.

The comparator (e.g., comparator COMP in FIG. 2) may sequentially compare the reset voltage RST, the first signal voltage SIG1 and the sum signal voltage SIGS with the voltage of the ramp signal RAMP. The counter may count the time during which each of the reset voltage RST, the first signal voltage SIG1 and the sum signal voltage SIGS is higher than a voltage of the ramp signal RAMP. The peripheral circuit 211 may calculate a difference between the reset count value obtained by counting the reset voltage RST and the first signal count value obtained by counting the first signal voltage SIG1, and may generate a first image signal corresponding to the charges generated in the first to sixth photodiodes PD1 to PD6. In some example embodiments, the peripheral circuit 211 may calculate a difference between the reset count value obtained by counting the reset voltage RST and the sum signal count value obtained by counting the sum signal voltage SIGS, and may generate a sum image signal corresponding to the charges generated by the N² photodiodes PD1 to PD9.

The peripheral circuit 211 may generate a second image signal corresponding to the charges generated by the seventh to ninth photodiodes PD7 to PD9 by subtracting the first image signal from the sum image signal. The peripheral circuit 211 may generate a phase signal pair corresponding to the phase information on an object, by utilizing an average value of the first image signal relatively disposed on the left side and the average value of the second image signal relatively disposed on the right side within one pixel. The peripheral circuit 211 may calculate the disparity based on the phase signal pair and may perform an autofocus function using the disparity.

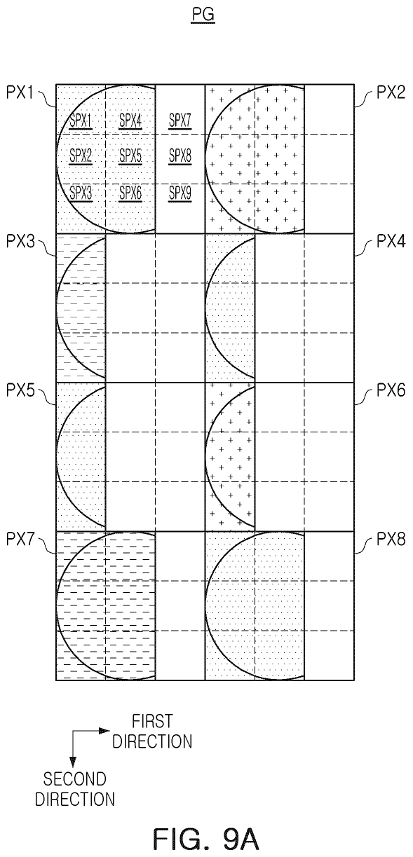

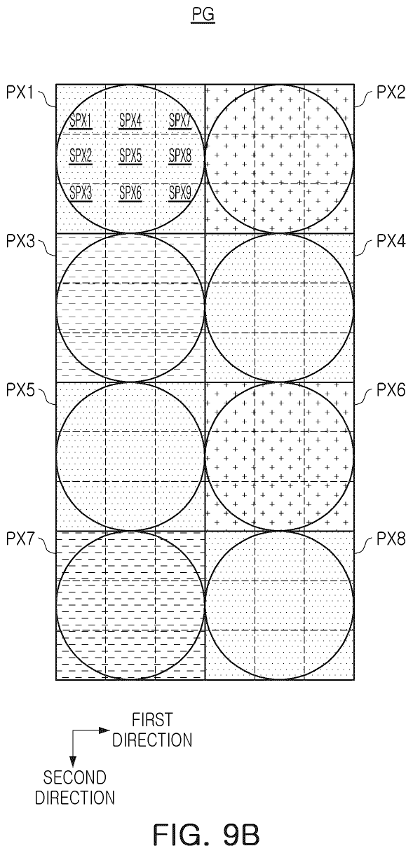

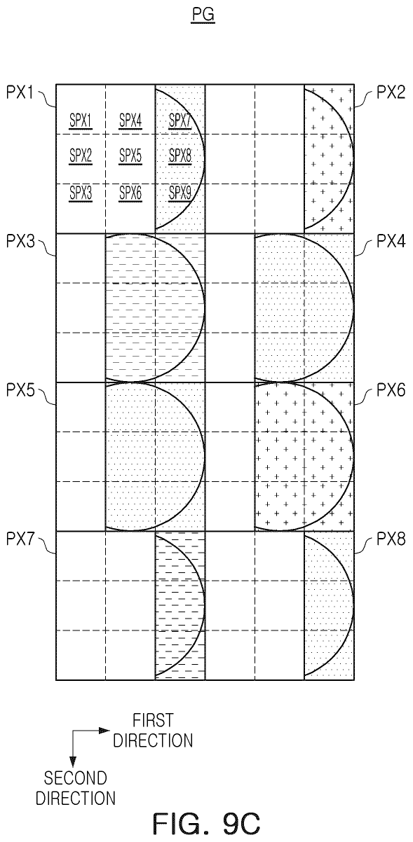

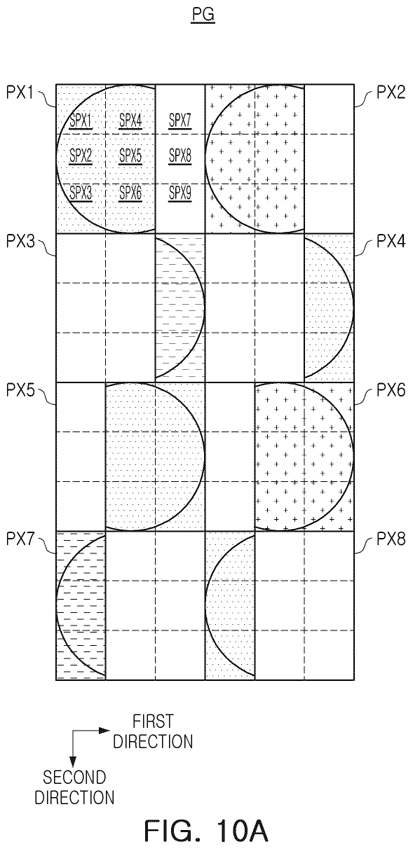

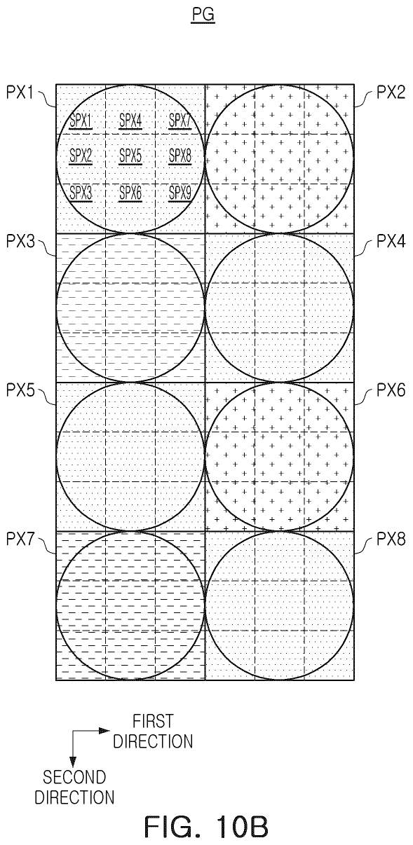

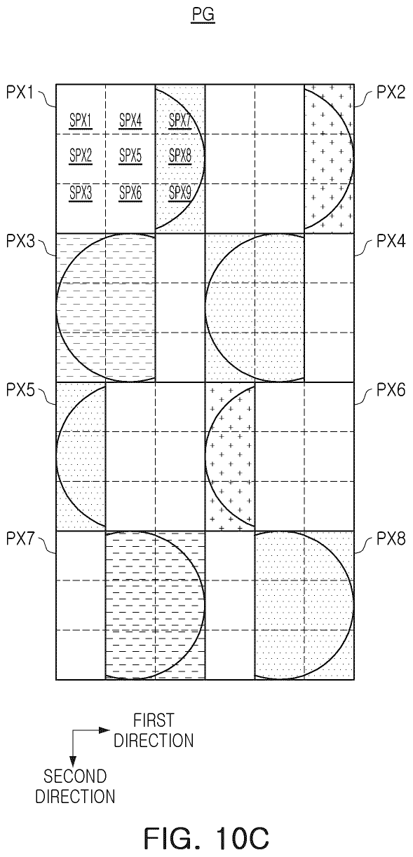

FIGS. 9A to 9C and 10A to 10C are plan views of an image signal according to some example embodiments of the present disclosure.

FIGS. 9A to 9C and FIGS. 10A to 10C illustrate an operation of one pixel group in a pixel array included in an image sensor according to some example embodiments of the present disclosure. In some example embodiments described with reference to FIGS. 9A to 9C and FIGS. 10A to 10C, one pixel group PG may include eight pixels PX1 to PX8 disposed in a 4×2 array. In some example embodiments, each of the pixels PX1 to PX8 may include nine pixel regions SPX1 to SPX9 sharing one microlens. Similar to the above-described explanation, each of the pixel regions SPX1 to SPX9 may include a photodiode and a transfer transistor. In some example embodiments, each of the pixels PX1 to PX8 may include a N² photodiodes and a corresponding N² transfer transistors

FIG. 9A illustrates pixel regions in which charges corresponding to a first image signal are generated in one pixel group PG. Referring to FIG. 9A, the first to sixth pixel regions SPX1 to SPX6 included in each of a first pixel PX1, a second pixel PX2, a seventh pixel PX7 and an eighth pixel PX8, and the first to third pixel regions SPX1 to SPX3 included in each of the third to sixth pixels PX3 to PX6 may output a first image signal. In other words, the first image signal may correspond to charges generated in the first to sixth pixel regions SPX1 to SPX6 included in each of the first pixel PX1, the second pixel PX2, the seventh pixel PX7 and the eighth pixel PX8, and charges generated in the first to third pixel regions SPX1 to SPX3 included in each of the third to sixth pixels PX3 to PX6. The 36 pixel regions generating charges corresponding to the first image signal may be defined as pixel regions of the first group, among the 72 pixel regions included in the pixel group PG.

FIG. 9B illustrates pixel regions in which charges corresponding to the sum image signal are generated in one pixel group PG. Referring to FIG. 9B, the sum image signal may correspond to charges generated in each of the pixel regions SPX1 to SPX9 of all the pixels PX1 to PX8 included in the pixel group PG.

FIG. 9C illustrates pixel regions in which charges corresponding to the second image signal are generated in one pixel group PG. The second image signal may correspond to charges generated in the seventh to ninth pixel regions SPX7 to SPX9 included in each of the first pixel PX1, the second pixel PX2, the seventh pixel PX7 and the eighth pixel PX8, and charges generated in the fourth to ninth pixel regions SPX4 to SPX9 included in each of the third to sixth pixels PX3 to PX6. The 36 pixel regions generating charges corresponding to the second image signal may be defined as pixel regions of the second group, among the 72 pixel regions included in the pixel group PG.

FIG. 10A illustrates pixel regions in which charges corresponding to the first image signal are generated in one pixel group PG. Referring to FIG. 10A, the first to sixth pixel regions SPX1 to SPX6 included in each of the first pixel PX1 and the second pixel PX2, the seventh to ninth pixel regions SPX7 to SPX9 included in each of the third pixel PX3 and the fourth pixel PX4, the fourth to ninth pixel regions SPX4 to SPX9 included in each of the fifth pixel PX5 and the sixth pixel PX6, and the first to third pixel regions SPX1 to SPX3 included in each of the seventh pixel PX7 and the eighth pixel PX8 may output a first image signal. The pixel regions generating charges corresponding to the first image signal may be defined as pixel regions of a first group, among 72 pixel regions included in the pixel group PG.

FIG. 10B illustrates pixel regions in which charges corresponding to the sum image signal are generated in one pixel group PG. Referring to FIG. 10B, the sum image signal may correspond to the charges generated in each pixel region SPX1 to SPX9 of all pixels PX1 to PX8 included in the pixel group PG.

FIG. 10C illustrates pixel regions in which charges corresponding to the second image signal are generated in one pixel group PG. The second image signal may correspond to charges generated in the seventh to ninth pixel regions SPX7 to SPX9 included in each of the first pixel PX1 and the second pixel PX2, charges generated in the first to sixth pixel regions SPX1 to SPX6 included in each of the third pixel PX3 and the fourth pixel PX4, charges generated in the first to third pixel regions SPX1 to SPX3 included in each of the fifth pixel PX5 and the sixth pixel PX6, and charges generated in the fourth to ninth pixel regions SPX4 to SPX9 included in each of the seventh pixel PX7 and the eighth pixel PX8. The pixel regions generating charges corresponding to the second image signal may be defined as pixel regions of a second group, among 72 pixel regions included in the pixel group PG.

In some example embodiment illustrated in FIGS. 9A to 9C and 10A to 10C, pixel group PG may include some pixels adjacent to each other and turning on different number of transfer transistors prior to second redout operation (e.g., at a time t1). For example, the pixel group PG may include a first pixel and a second pixel adjacent to the first pixel. The first pixel may include P transfer transistors configured to be turned on at the time t1 and L transfer transistors configured to be turned on at the time t2, where P and L may be integers. The second pixel may include T transfer transistors configured to be turned on at the time t1, wherein T may be an integer. For example, T may be different from P. For example, T may be same as L. For example, P may be greater than N²/2. For example, L may be equal to or greater than 2.

For example, referring to FIG. 9A, the first pixel PX1 and the third pixel PX3 may be adjacent in the second direction. At the time t1, 6 transfer transistors (e.g., of the pixel regions SPX1 to SPX6) included in the first pixel PX1 may be turned on, whereas 3 transfer transistors (e.g., of the pixel regions SPX1 to SPX3) included in the third pixel PX3 may be turned on. For example, referring to FIG. 10A, the first pixel PX1 and the third pixel PX3 may be adjacent in the second direction. At the time t1, 6 transfer transistors (e.g., of the pixel regions SPX1 to SPX6) included in the first pixel PX1 may be turned on, whereas 3 transfer transistors (e.g., of the pixel regions SPX7 to SPX9) included in the third pixel PX3 may be turned on.

In some example embodiments illustrated in FIGS. 9A to 9C and 10A to 10C, the number of pixel regions of the first group may be equal to the number of pixel regions of the second group, and may be 36. For example, the peripheral circuit 211 may obtain each of the first image signal and the sum image signal of the pixel group PG, and may subtract the first image signal from the sum image signal to obtain the second image signal of the pixel group PG.

In some example embodiments of the present disclosure, a left image signal and a right image signal required to implement an autofocus function may be obtained by utilizing the first image signal and the second image signal. For example, in some example embodiments illustrated in FIGS. 9A to 9C, the left image signal may correspond to the first image signal, and the right image signal may correspond to the second image signal. For example, the left image signal may correspond to charges generated in the first to sixth pixel regions SPX1 to SPX6 included in each of the first pixel PX1, the second pixel PX2, the seventh pixel PX7 and the eighth pixel PX8, and charges generated in the first to third pixel regions SPX1 to SPX3 included in each of the third to sixth pixels PX3 to PX6. The right image signal may correspond to charges generated in the seventh to ninth pixel regions SPX7 to SPX9 included in each of the first pixel PX1, the second pixel PX2, the seventh pixel PX7 and the eighth pixel PX8, and charges generated in the fourth to ninth pixel regions SPX4 to SPX9 included in each of the third to sixth pixels PX3 to PX6.

In some example embodiments, in some example embodiments illustrated in FIGS. 10A to 10C, one portion of each of the left image signal and the right image signal may be included in the first image signal, and the other portion of each of the left image signal and the right image signal may be included in the second image signal. In some example embodiments illustrated in FIGS. 10A to 10C, the left image signal may correspond to charges generated in the first to sixth pixel regions SPX1 to SPX6 included in each of the first to fourth pixels PX1 to PX4, and charges generated in the first to third pixel regions SPX1 to SPX3 included in each of the fifth to eighth pixels PX5 to PX8. The right image signal may correspond to charges generated in the seventh to ninth pixel regions SPX7 to SPX9 included in each of the first to fourth pixels PX1 to PX4, and charges generated in the fourth to ninth pixel regions SPX4 to SPX9 included in each of the fifth to eighth pixels PX5 to PX8.

The peripheral circuit 211 or the image signal processor 220 may drive the pixel group PG as a single unit and may calculate an average value of the left image signal and an average value of the right image signal. Referring to FIGS. 9A to 9C and FIGS. 10A to 10C, within one pixel group PG, the number of pixel regions generating charges corresponding to the left image signal by color may be equal to the number of pixel regions generating charges corresponding to the right image signal by color. In some example embodiments, nine pixel regions may be included for each of red pixels PX2 and PX6 and the blue pixels PX3 and PX7. In some example embodiments, 18 pixel regions may be included for each of the green pixels PX1, PX4, PX5, and PX8.

The peripheral circuit 211 or the image signal processor 220 may obtain a phase signal pair corresponding to phase information on the object based on an average value of the left image signal and an average value of the right image signal. The image signal processor may calculate the disparity for the object using a pair of phase signals. For example, two phase signals output from the same object may have different coordinates, and a disparity corresponding to the difference in the coordinates may be calculated.

The image signal processor 220 may generate a control signal for implementing an autofocus function based on the calculated disparity. In some example embodiments, the lens driver may adjust a position of at least one of the lenses included in the lens unit based on a control signal to adjust the focus on the object. According to some example embodiments, the processor may control the lens driver in response to the received control signal to adjust the focus on the object. In this manner, a PDAF operation may be performed using pixels including odd pixel regions. Through this, angles of light incident on the pixel array may be identified more precisely while maintaining a high resolution, thereby improving the autofocus function.

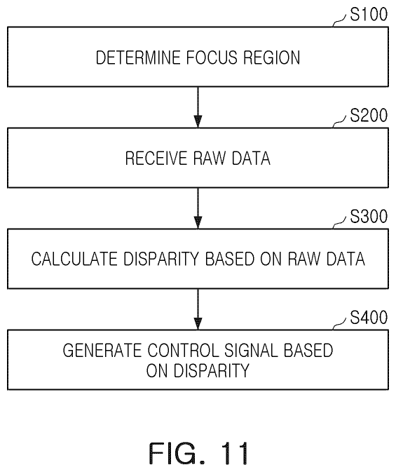

FIGS. 11 to 13 are flowcharts of an operation of an image sensor according to some example embodiments of the present disclosure. FIGS. 11 to 13 are flowcharts illustrating example operations when a pixel according to some example embodiments of the present disclosure is a pixel described with reference to FIG. 6. It is understood that additional operations can be provided before, during, and after the operations in FIGS. 11 to 13, and some of the operations described below can be replaced or eliminated, for additional embodiments of the method. The order of the operations/processes may be interchangeable, or two or more operations can be performed simultaneously.

The image signal processor may determine a partial region of an entire region of an image being captured as a focus region (S100). For example, the image signal processor may determine a focus region from a user input, or may determine a focus region based on object information of the image. As another example, the image signal processor may recognize an object included in the image based on image data provided from the pixel array. When a specific region of the object included in the image, for example, a face, is recognized, the image signal processor may determine a region including the face as the focus region. However, a method of determining the focus region is not limited thereto, and the focus region may be determined by the processor according to some example embodiments.

The image signal processor may receive raw data output from the pixel array (S200). In some example embodiments, the raw data may include a first image signal and a sum image signal, or may include a first image signal and a second image signal. The image signal processor may calculate the disparity for the object based on the raw data (S300). For example, the image signal processor may calculate the disparity corresponding to the raw data output by a plurality of pixel groups corresponding to the focus region. As another example, the image signal processor may calculate the disparity corresponding to all the raw data received from the pixel array.

The image signal processor may generate a control signal based on the disparity (S400). The control signal may be a signal for adjusting the focus from the object. In some example embodiments, the lens driver may adjust a distance between the lens and the object based on the control signal. According to some example embodiments, the processor may control the lens driver to adjust the position of the lens based on the control signal, thereby adjusting the distance between the lens and the object.

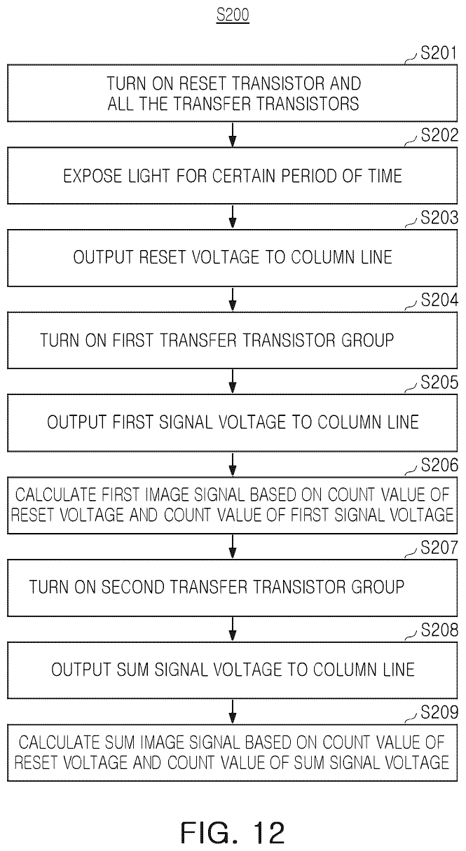

FIG. 12 illustrates operation S200 among the operation stages described with reference to FIG. 11. FIG. 11 is a flowchart illustrating a process in which an image sensor according to some example embodiments of the present disclosure reads pixel signals based on an RSS readout method.

The reset transistor RX and the N² transfer transistors may be turned on (S201), and a reset operation in which charges of the floating diffusion region FD and the N² photodiodes PD1-PD9 are removed, or otherwise reduced, may be performed. Then, the reset transistor RX and the N² transfer transistors may be turned off to start an exposure section. During the exposure section, light may be exposed to the pixel (S202). Charges may be generated in photodiodes included in the pixel. The pixel may output a reset voltage to a column line as a pixel signal (S203).

In a first readout section, the comparator may compare the reset voltage output by the pixel to the column line with a voltage of the ramp signal. A reset count value obtained by counting the reset voltage may be stored in a latch or a memory of a buffer circuit inside the counter.

Prior to a second readout operation, a first transfer signal group may be transitioned to a voltage corresponding to logic high. The first transfer transistor group may be turned on by transfer signals included in the first transfer signal group (S204), so that the charge of the photodiodes connected to the turned-on transfer transistors may move to the floating diffusion region. The pixel may output the first signal voltage corresponding to the charges accumulated in the floating diffusion region to the column line (S205).

In a second readout section, the comparator may compare the first signal voltage output by the pixel PX to the column line with the voltage of the ramp signal RAMP. A first count value obtained by counting the first signal voltage may be stored in a memory of a latch or a buffer circuit inside the counter. The peripheral circuit may calculate a first image signal based on the reset count value and the first count value (S206).

Prior to a third readout operation, a second transfer signal group may be transitioned to a voltage corresponding to logic high. The second transfer transistor group may be turned on by the transfer signals included in the second transfer signal group (S207). Charges of photodiodes connected to the turned-on transfer transistors may move to the floating diffusion region. The pixel may output a sum signal voltage corresponding to the charges accumulated in the floating diffusion region to the column line (S208).

In a third readout section, the comparator may compare the sum signal voltage output by the pixel to the column line with the voltage of the ramp signal RAMP. A sum count value obtained by counting the sum signal voltage may be stored in a memory of a latch or a buffer circuit inside the counter. The peripheral circuit 211 may calculate a sum image signal based on the reset count value and the sum signal count value (S209).

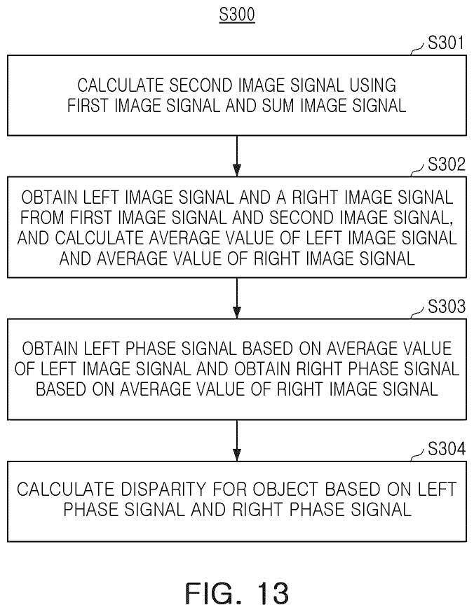

FIG. 13 illustrates operation S300 among the operation stages described with reference to FIG. 11. FIG. 13 is a flowchart for a case in which operation S200 is performed as an RSS readout operation as described with reference to FIGS. 8A to 8C above.

A second image signal may be calculated using the first image signal and the sum image signal (S301). In some example embodiments, the peripheral circuit may calculate a second image signal by subtracting the first image signal from the sum image signal.

A left image signal and a right image signal, among the pixel signals included in the first image signal and the second image signal, may be identified from each other, and an average value of the left image signal and an average value of the right image signal may be calculated (S302). In some example embodiments, an average value of the image signal may be calculated through a binning operation for the left image signal and the right image signal.

A left phase signal may be obtained based on an average value of the left image signal, and a right phase signal may be obtained based on an average value of the right image signal (S303). The peripheral circuit may use an average value of the first image signal relatively disposed on the left side and an average value of the second image signal relatively disposed on the right side within a pixel, thus calculating a phase signal pair corresponding to phase information on the object. The left phase signal may correspond to the left phase information, and the right phase signal may correspond to the right phase information.

The disparity for the object may be calculated based on the left phase signal and the right phase signal (S304). The peripheral circuit may calculate a disparity based on the phase signal pair and may perform an autofocus function using the disparity.

An image sensor, according to some example embodiments of the present disclosure, may perform a PDAF operation using pixels including an odd number of pixel regions. As a result, angles of light incident on the pixel array may be identified with a relatively higher precision while maintaining a relatively higher resolution when performing the autofocus function, and the autofocus function may be improved.

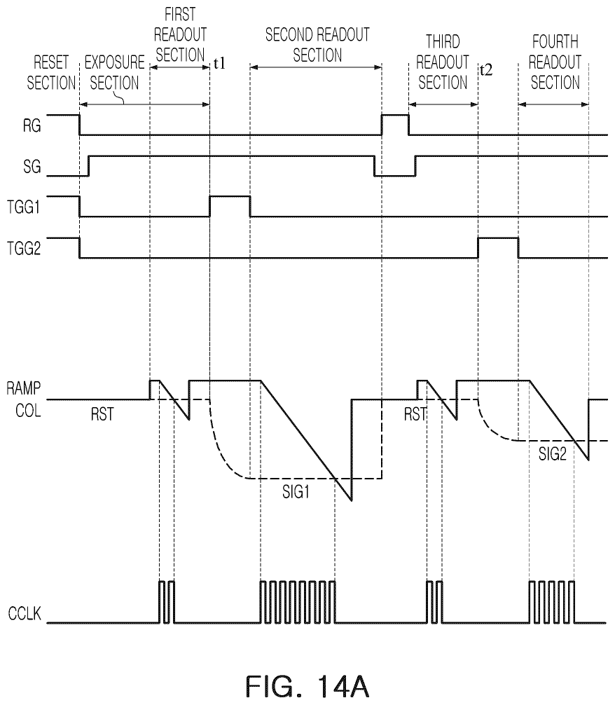

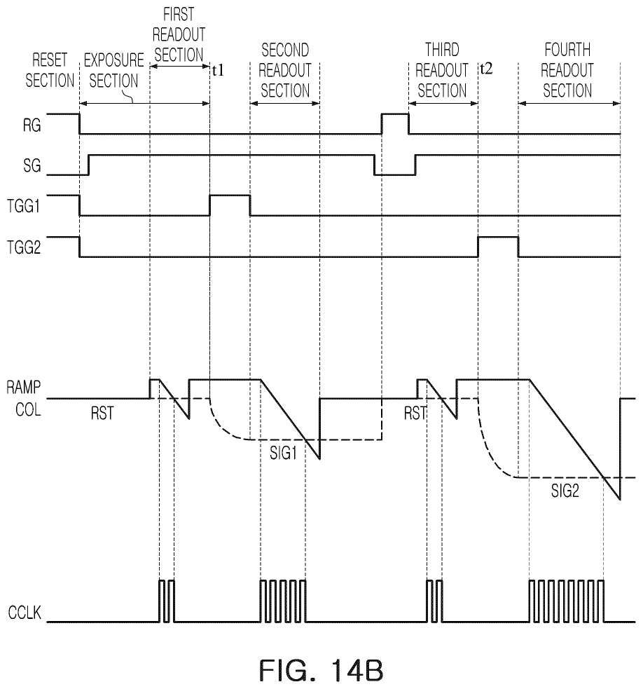

FIGS. 14A and 14B are timing diagrams of a readout operation of a pixel according to some example embodiments of the present disclosure. FIG. 14A and FIG. 14B are timing diagrams for the readout operation of the pixel PX described with reference to FIG. 6.

Referring to FIG. 14A and FIG. 14B, an image sensor according to some example embodiments of the present disclosure may measure pixel signals based on a Reset-Signal-Reset-Signal (RSRS) readout method, unlike some example embodiments described with reference to FIG. 7 above. For example, the image sensor may measure a reset voltage RST and a first signal voltage SIG1 and may then output a first image signal based on the difference therebetween, and may measure a reset voltage RST and a second signal voltage SIG2 and may then output a second image signal based on the difference therebetween.

FIG. 14A is a timing diagram for a case in which the number of pixel regions that output pixel signals corresponding to the first pixel signal SIG1 is greater than the number of pixel regions that output pixel signals corresponding to the second pixel signal SIG2. For example, a difference in levels of the first pixel signal SIG1 and the reset voltage RST may be greater than a difference in levels of the second pixel signal SIG2 and the reset voltage RST. FIG. 14B is a timing diagram for a case in which the number of pixel regions that output pixel signals corresponding to the second pixel signal SIG2 is greater than the number of pixel regions that output pixel signals corresponding to the first pixel signal SIG1. In this case, a difference in the levels of the first pixel signal SIG1 and the reset voltage RST may be smaller than a difference in the levels of the second pixel signal SIG2 and the reset voltage RST.

Referring to FIG. 6, FIG. 14A and FIG. 14B together, a reset operation in which the reset transistor RX and the N² transfer transistors are turned on may be performed to remove the charges of the floating diffusion region FD and the N² photodiodes PD1 to PD9. Then, the reset transistor RX and the N² transfer transistors may be turned off to start an exposure section. During the exposure section, the pixel PX may be exposed to light. The N² photodiodes PD1 to PD9 included in the pixel PX receiving the light may generate and may accumulate charges in proportion to the incident light.

In the first readout section, the comparator may compare the reset voltage RST output by the pixel PX to the column line COL with the voltage of the ramp signal RAMP. In some example embodiments illustrated in FIGS. 14A and 14B, the counter may count the time when the reset voltage RST is lower than the voltage of the ramp signal RAMP. The reset count value obtained by counting the reset voltage RST may be stored in a memory of a latch or a buffer circuit inside the counter.

Prior to the second readout operation, the first transfer signal group TGG1 may be transitioned to a voltage corresponding to logic high. The first transfer signal group TGG1 may include transfer signals input to P transfer transistors included in some of the plurality of pixel regions SPX1 to SPX9. For example, referring to FIG. 14A, the first transfer signal group TGG1 may include the first to third transfer signals TG1 to TG3, or the fourth to ninth transfer signals TG4 to TG9. Alternatively, referring to FIG. 14B, the first transfer signal group TGG1 may include the seventh to ninth transfer signals TG7 to TG9, or the first to sixth transfer signals TG1 to TG6.

The P transfer transistors may be turned on (e.g., at the time t1) by the transfer signals included in the first transfer signal group TGG1, and the charges of the photodiodes connected to the turned-on transfer transistors may move to the floating diffusion region FD. The pixel PX may output a first signal voltage SIG1 corresponding to the charges accumulated in the floating diffusion region FD to the column line COL.

In the second readout section, the comparator may compare the first signal voltage SIG1 output by the pixel PX to the column line COL with the voltage of the ramp signal RAMP. In some example embodiments illustrated in FIGS. 14A and 14B, the counter may count the time during which the first signal voltage SIG1 is lower than the voltage of the ramp signal RAMP. A first count value obtained by counting the first signal voltage SIG1 may be stored in a memory of a latch or a buffer circuit within the counter.

Prior to the third readout section, the reset signal RG may transition to a voltage corresponding to logic high. Accordingly, the reset transistor RX may be turned on to perform a reset operation in which the charge of the floating diffusion region FD is removed, or otherwise reduced. The pixel PX may output the reset voltage RST of the floating diffusion region FD to the column line COL.

In the third readout section, the comparator may compare the reset voltage RST output by the pixel PX to the column line COL with the voltage of the ramp signal RAMP, similarly to the first readout section. In some example embodiments illustrated in FIGS. 14A and 14B, the counter may count the time when the reset voltage RST is lower than the voltage of the ramp signal RAMP.

Prior to the fourth readout operation, the second transfer signal group TGG2 may transition to a voltage corresponding to logic high. The second transfer signal group TGG2 may include the remaining transfer signals not included in the first transfer signal group TGG1, among the transfer signals TG1 to TG9. Referring to FIG. 14A, for example, when the first transfer signal group TGG1 is the first to sixth transfer signals TG1 to TG6, the second transfer signal group TGG2 may be the seventh to ninth transfer signals TG7 to TG9. As another example, when the first transfer signal group TGG1 is the fourth to ninth transfer signals TG4 to TG9, the second transfer signal group TGG2 may be the first to third transfer signals TG1 to TG3. Referring to FIG. 14B, for example, when the first transfer signal group TGG1 is the first to third transfer signals TG1 to TG3, the second transfer signal group TGG2 may be the fourth to ninth transfer signals TG4 to TG9. As another example, when the first transfer signal groups TGG1 are the seventh to ninth transfer signals TG7 to TG9, the second transfer signal groups TGG2 may be the first to sixth transfer signals TG1 to TG6.

The L transfer transistors may be turned on (e.g., at the time t2) by the transfer signals included in the first transfer signal group TGG2, so that the charges of the photodiodes connected to the turned-on transfer transistors may move to the floating diffusion region FD. The pixel PX may output the second signal voltage SIG2 corresponding to the charges accumulated in the floating diffusion region FD to the column line COL.

In the fourth readout section, the comparator may compare the second signal voltage SIG2 output by the pixel PX to the column line COL with the voltage of the ramp signal RAMP. In some example embodiments illustrated in FIGS. 14A and 14B, the counter may count the time during which the second signal voltage SIG2 is lower than the voltage of the ramp signal RAMP. The second count value obtained by counting the second signal voltage SIG2 may be stored in a memory of a latch or a buffer circuit within the counter.

In some example embodiments, a signal range of the first pixel signal SIG1 and a signal range of the second pixel signal SIG2 may be different from each other. In some example embodiments, a range of the code value provided as the counting clock CCLK in the second readout section, for example, the number of clocks toggled, may be different from a range of a code value provided in the fourth readout section.

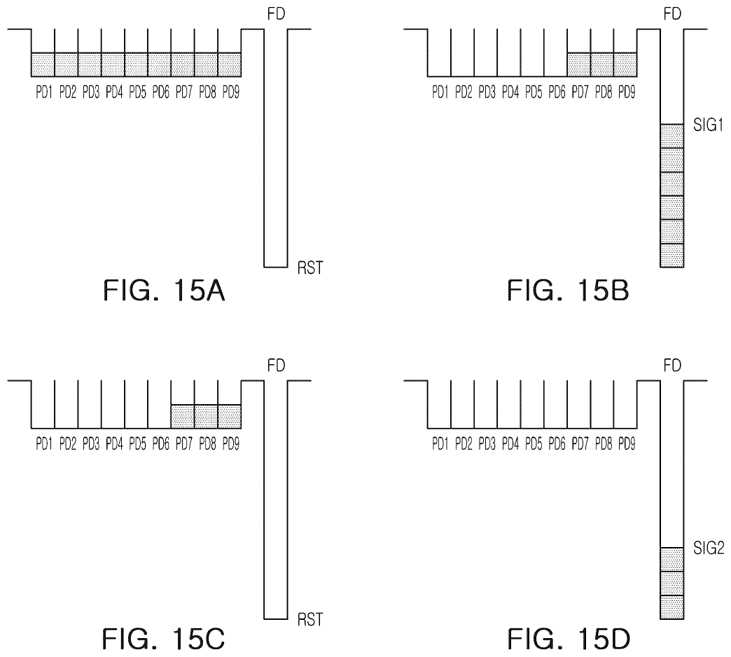

FIGS. 15A to 15D are views illustrating a movement of charges in a readout operation according to some example embodiments of the present disclosure. FIGS. 15A to 15C may be a view roughly illustrating a floating diffusion region included in one pixel and energy levels of a plurality of photodiodes. FIG. 15A, FIG. 15B, FIG. 15C and FIG. 15D may correspond to energy levels of a pixel in the first readout operation, the second readout operation and the third readout operation, among the readout operations of the pixel PX described with reference to FIG. 14A above, respectively. For convenience of explanation, in some example embodiments illustrated in FIGS. 8A to 8C, it is assumed that the first transfer signal group includes the first to sixth transfer signals in some example embodiments according to FIG. 14A, but the present disclosure is not limited thereto.

Referring to FIG. 15A, during an exposure section, each of the photodiodes PD1 to PD9 may generate charges in response to light. In the exposure section, the floating diffusion region FD may be in a reset state and thus may have a potential corresponding to the reset voltage RST. During the first readout section, the pixel may output the reset voltage RST corresponding to the potential of the floating diffusion region FD.

Referring to FIG. 15B, prior to the second readout section, the first to sixth transfer transistors may be turned on by the first to sixth transfer signals included in the first transfer signal group. Accordingly, charges generated in the first to sixth photodiodes PD1 to PD6 may move to the floating diffusion region FD. The floating diffusion region FD may have a potential corresponding to the first signal voltage SIG1. During the second readout section, the pixel may output the first signal voltage SIG1 corresponding to the potential of the floating diffusion region FD.

Referring to FIG. 15C, the floating diffusion region FD may be in a reset state, and thus may have a potential corresponding to the reset voltage RST. During the third readout section, the pixel may output a reset voltage RST corresponding to the potential of the floating diffusion region FD.

Referring to FIG. 15D, prior to the fourth readout section, the seventh to ninth transfer transistors may be turned on by the seventh to ninth transfer signals included in the second transfer signal group different from the first transfer signal group. Accordingly, charges generated in the seventh to ninth photodiodes PD7 to PD9 may move to the floating diffusion region FD. Referring to FIG. 15D, before the fourth readout section starts, charges generated in the seventh to nineth photodiodes PD7 to PD9 may be accumulated in the floating diffusion region FD. The floating diffusion region FD may have a potential corresponding to the second signal voltage SIG2. During the fourth readout section, the pixel may output the second signal voltage SIG2 corresponding to the potential of the floating diffusion region FD.

The comparator may sequentially compare the reset voltage RST, the first signal voltage SIG1 and the second signal voltage SIG2 with the voltage of the ramp signal RAMP. The counter may count the time during which each of the reset voltage RST, the first signal voltage SIG1 and the second signal voltage SIG2 is higher than the voltage of the ramp signal RAMP. The peripheral circuit may calculate a difference between the reset count value obtained by counting the reset voltage RST and the first signal count value obtained by counting the first signal voltage SIG1, and may generate a first image signal corresponding to the charges generated in the first to sixth photodiodes PD1 to PD6. In some example embodiments, the peripheral circuit may calculate a difference between a reset count value obtained by counting the reset voltage RST and a sum signal count value obtained by counting the second signal voltage SIG2, and may generate a sum image signal corresponding to the charges generated by the N² photodiodes PD1 to PD9.

The peripheral circuit may use an average value of the first image signal relatively disposed to the left and an average value of the second image signal relatively disposed to the right within one pixel, and may calculate a phase signal pair corresponding to phase information on the object. The peripheral circuit may calculate a disparity based on the phase signal pair and may perform an autofocus function using the disparity.

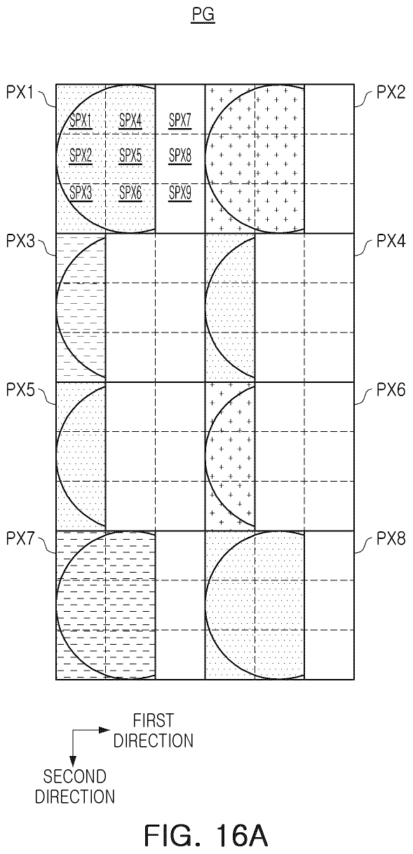

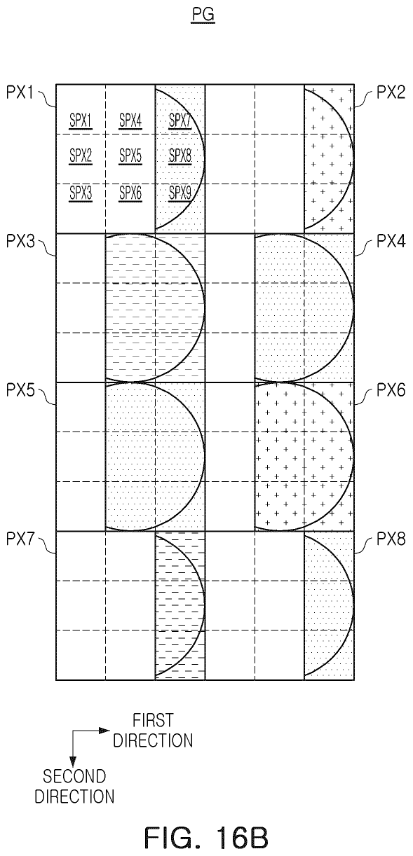

FIGS. 16A and 16B are plan views of an image signal according to some example embodiments of the present disclosure.

FIGS. 16A and 16B illustrate an operation of one pixel group in a pixel array included in an image sensor according to some example embodiments of the present disclosure. In some example embodiments described with reference to FIGS. 16A and 16B, one pixel group PG may include eight pixels PX1 to PX8 disposed in a 4×2 form. In some example embodiments, each of the pixels PX1 to PX8 may include nine pixel regions SPX1 to SPX9 sharing one microlens, and each of the nine pixel regions SPX1 to SPX9 may include a photodiode.

FIG. 16A illustrates pixel regions in which charges corresponding to a first image signal are generated in one pixel group PG. Referring to FIG. 16A, the first to sixth pixel regions SPX1 to SPX6 included in each of the first pixel PX1, the second pixel PX2, the seventh pixel PX7 and the eighth pixel PX8, and the first to third pixel regions SPX1 to SPX3 included in each of the third to sixth pixels PX3 to PX6 may output the first image signal. In other words, the first image signal may correspond to the charges generated in the first to sixth pixel regions SPX1 to SPX6 included in each of the first pixel PX1, the second pixel PX2, the seventh pixel PX7 and the eighth pixel PX8, and the charges generated in the first to third pixel regions SPX1 to SPX3 included in each of the third to sixth pixels PX3 to PX6. The pixel regions generating charges corresponding to the first image signal may be defined as pixel regions of the first group, among 72 pixel regions included in the pixel group PG.

FIG. 16B illustrates pixel regions in which charges corresponding to the second image signal are generated in one pixel group PG. The second image signal may correspond to charges generated in the seventh to ninth pixel regions SPX7 to SPX9 included in each of the first pixel PX1, the second pixel PX2, the seventh pixel PX7 and the eighth pixel PX8, and charges generated in the fourth to nineth pixel regions SPX4 to SPX9 included in each of the third to sixth pixels PX3 to PX6. The pixel regions generating charges corresponding to the second image signal may be defined as pixel regions of the second group, among the 72 pixel regions included in the pixel group PG.

For example, referring to FIG. 16A, the first pixel PX1 and the third pixel PX3 may be adjacent in the second direction. At the time t1, 6 transfer transistors (e.g., SPX1 to SPX6) included in the first pixel PX1 may be turned on, whereas 3 transfer transistors (e.g., SPX1 to SPX3) included in the third pixel PX3 may be turned on.

In some example embodiments illustrated in FIGS. 16A and 16B, the number of pixel regions of the first group may be equal to the number of pixel regions of the second group, and may be 36. For example, the peripheral circuit 211 may obtain each of the first image signal and the second image signal of the pixel group PG

In some example embodiments of the present disclosure, the left image signal and the right image signal required to implement the autofocus function may be obtained using the first image signal and the second image signal. For example, in some example embodiments illustrated in FIGS. 16A and 16B, the left image signal may correspond to the first image signal, and the right image signal may correspond to the second image signal. In some example embodiments, the left image signal may correspond to the charges generated in the first to sixth pixel regions SPX1 to SPX6 included in each of the first pixel PX1, the second pixel PX2, the seventh pixel PX7 and the eighth pixel PX8 and the charges generated in the first to third pixel regions SPX1 to SPX3 included in each of the third to sixth pixels PX3 to PX6. The right image signal may correspond to the charges generated in the seventh to ninth pixel regions SPX7 to SPX9 included in each of the first pixel PX1, the second pixel PX2, the seventh pixel PX7 and the eighth pixel PX8, and the charges generated in the fourth to ninth pixel regions SPX4 to SPX9 included in each of the third to sixth pixels PX3 to PX6.

The peripheral circuit 211 or the image signal processor 220 may drive the pixel group PG as a single unit and may calculate an average value of the left image signal and an average value of the right image signal. Referring to FIGS. 9A to 9C and FIGS. 10A to 10C, within one pixel group PG, the number of pixel regions generating charges corresponding to the left image signal by color may be equal to the number of pixel regions generating charges corresponding to the right image signal by color. For example, nine pixel regions may be included for each red pixel PX2 and PX6 and each blue pixel PX3 and PX7. In some example embodiments, 18 pixel regions may be included for each green pixel PX1, PX4, PX5, and PX8.

The peripheral circuit 211 or the image signal processor 220 may obtain a phase signal pair corresponding to phase information on the object based on an average value of the left image signal and an average value of the right image signal. The image signal processor may calculate a disparity for the object using the phase signal pair. For example, two phase signals output from the same object may have different coordinates, and the disparity corresponding to the difference in the coordinates may be calculated.

The image signal processor 220 may generate a control signal for implementing an autofocus function based on the calculated disparity. In some example embodiments, the lens driver may adjust a position of at least one of the lenses included in the lens unit based on the control signal to adjust the focus for the object. According to some example embodiments, the processor may control the lens driver in response to the received control signal to adjust the focus for the object. In this manner, the PDAF operation may be performed using pixels including odd pixel regions. Through this, the autofocus function may be improved by further identifying the angles of the light incident on the pixel array while maintaining a relatively higher resolution.

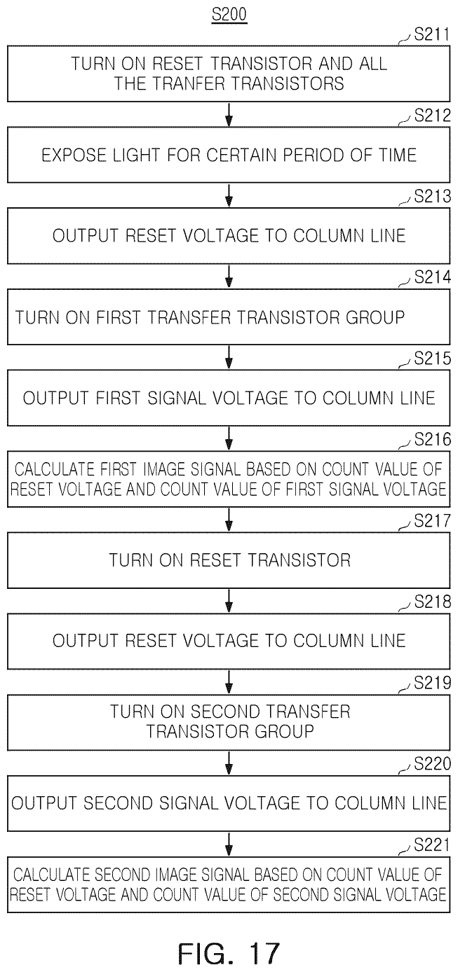

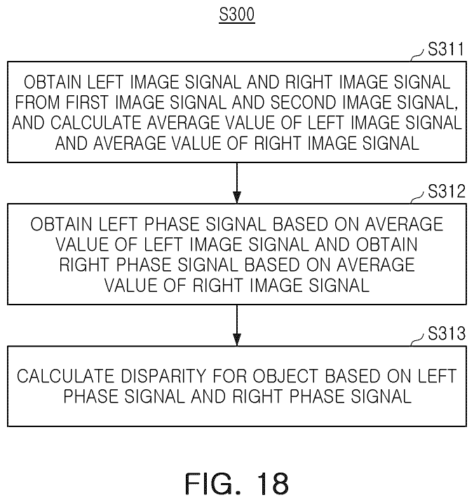

FIGS. 17 and 18 are flowcharts of the operation of an image sensor according to some example embodiments of the present disclosure. FIGS. 17 and 18 are flowcharts illustrating example operations when a pixel according to some example embodiments of the present disclosure is a pixel described with reference to FIG. 6. It is understood that additional operations can be provided before, during, and after the operations in FIGS. 17 and 18, and some of the operations described below can be replaced or eliminated, for additional embodiments of the method. The order of the operations/processes may be interchangeable, or two or more operations can be performed simultaneously.

FIG. 17 illustrates operation S200, among the operation stages described with reference to FIG. 11. FIG. 17 is a flowchart illustrating a process in which an image sensor, according to some example embodiments of the present disclosure, reads pixel signals based on an RSRS readout method.

A reset operation in which the reset transistor and the N² transfer transistors TG1-TG9 are turned on (S211), and the charges of the floating diffusion region FD and the N² photodiodes PD1-PD9 are removed, or otherwise reduced, may be performed. Then, the reset transistor and the N² transfer transistors TG1-TG9 may be turned off to start an exposure section. During the exposure section, light may be exposed to the pixel (S212). The photodiodes included in the pixel receiving light may generate and may accumulate charges in proportion to the incident light. The pixel may output a reset voltage as a pixel signal to the column line (S213).

In the first readout section, the comparator may compare the reset voltage output by the pixel to the column line with the voltage of the ramp signal. The reset count value obtained by counting the reset voltage may be stored in a memory of a latch or a buffer circuit inside the counter, or the like.

Prior to the second readout operation, the first transfer signal group TGG1 may be transitioned to a voltage corresponding to logic high. The first transfer transistor group may be turned on by transfer signals connected to the first transfer signal group TGG1 (S214). Charges of the photodiodes connected to the turned-on transfer transistors may move to the floating diffusion region FD. The pixel may output a first signal voltage corresponding to the charges accumulated in the floating diffusion region to the column line (S215).

In the second readout section, the comparator may compare the first signal voltage output by the pixel PX to the column line with the voltage of the ramp signal. The first count value obtained by counting the first signal voltage may be stored in a memory of a latch or a buffer circuit inside the counter, or the like. The peripheral circuit 211 may generate the first image signal based on the reset count value and the first count value (S216).

In the third readout section, the reset signal may transition to a voltage corresponding to logic high, and accordingly, the reset transistor may be turned on (S217), and a reset operation in which charges of the floating diffusion region FD are removed, or otherwise reduced, may be performed. The pixel may output the reset voltage of the floating diffusion region to the column line (S218).

Prior to the fourth readout operation, the second transfer signal group TGG2 may transition to a voltage corresponding to logic high. The second transfer transistor group may be turned on by transfer signals included in the second transfer signal group (S219). Charges of the photodiodes connected to the turned-on transfer transistors may move to the floating diffusion region FD. The pixel may output the second signal voltage corresponding to the charges accumulated in the floating diffusion region to the column line (S220).

In the fourth readout section, the comparator COMP may compare the second signal voltage output by the pixel to the column line with the voltage of the ramp signal. A second count value obtained by counting the second signal voltage may be stored in a memory of a latch or a buffer circuit inside the counter. The peripheral circuit may generate the second image signal based on the reset count value and the second signal count value (S221).

FIG. 18 is a flowchart of operation S300 among the operation stages described with reference to FIG. 11. FIG. 18 is a flowchart for the case in which operation S200 is performed as the RSRS readout operation as described with reference to FIG. 17 above. A series of operations of FIG. 18 may be similar to a series of operations described with reference to FIG. 12 above. It is understood that additional operations can be provided before, during, and after the operations in FIG. 18, and some of the operations described below can be replaced or eliminated, for additional embodiments of the method. The order of the operations/processes may be interchangeable, or two or more operations can be performed simultaneously. In some example embodiments, an operation of obtaining the second image signal (S301) may be omitted.

Among the pixel signals included in the first image signal and the second image signal, the left image signal and the right image signal may be identified or differentiated from each other, and an average value of the left image signal and an average value of the right image signal may be calculated (S311).

The left phase signal may be obtained based on the average value of the left image signal, and the right phase signal may be obtained based on the average value of the right image signal (S312). The peripheral circuit may use an average value of the first image signal relatively disposed on the left side and an average value of the second image signal relatively disposed on the right side within one pixel, thus calculating a phase signal pair corresponding to phase information on the object. The left phase signal may correspond to the left phase information, and the right phase signal may correspond to the right phase information.

The disparity for the object may be calculated based on the left phase signal and the right phase signal (S313). The peripheral circuit may calculate a disparity based on the phase signal pair, and may perform an autofocus function using the disparity.

An image sensor, according to some example embodiments of the present disclosure, may perform a phase detection autofocus (PDAF) operation using pixels including an odd number of pixel regions. As a result, angles of light incident on the pixel array may be identified more precisely while maintaining a high resolution when performing an autofocus function, and the autofocus function may thus be improved.

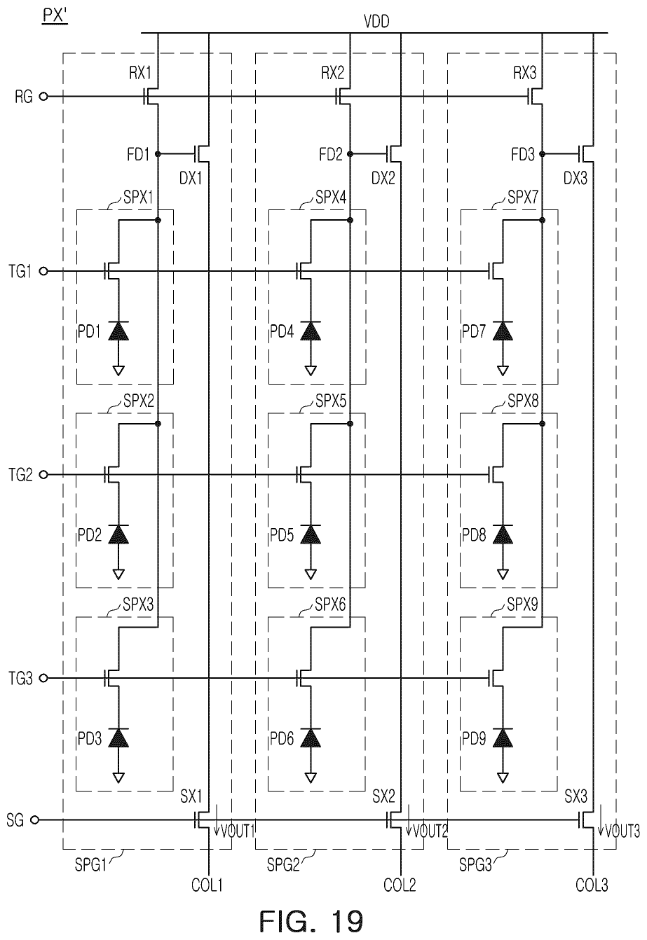

FIG. 19 is an example circuit diagram of a pixel PX′ of an image sensor according to some example embodiments of the present disclosure.

Referring to FIG. 19, the pixel PX′ according to some example embodiments of the present disclosure may include a plurality of sub-pixel groups SPG1 to SPG3 disposed in a first direction (e.g., horizontal direction in FIG. 19). The sub-pixel groups SPG1 to SPG3 may include a plurality of pixel regions disposed in a second direction orthogonal to the first direction. The sub-pixel regions SPX1 to SPX3 may share floating diffusion region FD1, the sub-pixel regions SPX4 to SPX6 may share floating diffusion region FD2, and the sub-pixel regions SPX7 to SPX9 may share floating diffusion region FD3. One pixel PX′ may include N² photodiodes PD1 to PD9, N² transfer transistors, reset transistors RX1-RX3, driving transistors DX1-DX3, and selection transistor SX1-SX3. Each of the plurality of pixel regions SPX1 to SPX9 included in one pixel PX′ may include a respective photodiode PD1 to PD9 and a respective transfer transistor. According to some example embodiments, one or more of the sub-pixel groups SPG1 to SPG3 in the one pixel PX′ may include two or more reset transistors, two or more driving transistors, and two or more selection transistors.

The reset transistors RX1-RX3 may be turned on by a reset signal RG to remove, or otherwise reduce, charges of the floating diffusion regions FD1, FD2 and FD3. Charges obtained from at least one of the connected photodiodes PD1 to PD9 may be moved and accumulated in the corresponding floating diffusion regions FD1 to FD3. The driving transistors DX1-DX3 may generate corresponding pixel signals VOUT1-VOUT3 by amplifying a voltage determined by charges accumulated in the corresponding floating diffusion regions FD1 to FD3. The selection transistors SX1-SX3 may be driven by a selection signal SG to output pixel signals VOUT1 to VOUT3 to the readout circuit through corresponding column lines COL1 to COL3. The pixel PX′ may be provided with power supply voltage VPIX. The power supply voltage VPIX may be connected to the one of the terminals (e.g., drain terminal) of each reset transistor RX1-RX3 and each driving transistor DX1-DX3.

The N² transfer transistors may be turned on by the transfer signals TG1 to TG9 to transmit the charges generated by the photodiodes PD1 to PD9 to the floating diffusion regions FD1 to FD3. The first column line COL1 may allow the charges generated by the first to third pixel regions SPX1 to SPX3 to move to the first floating diffusion region FD1 and may output the charges as the first pixel signal VOUT1. The second column line COL2 may allow the charges generated by the fourth to sixth pixel regions SPX4 to SPX6 to move to the second floating diffusion region FD2 and may output the charges as the second pixel signal VOUT2. The third column line COL3 may allow the charges generated by the seventh to ninth pixel regions SPX7 to SPX9 to move to the third floating diffusion region FD3 and may output the charges as the third pixel signal VOUT3.

For example, while the first transfer transistor TG1 is turned on by the first transfer signal TG1 received from the row driver, charges obtained from the first, fourth, and seventh photodiodes PD1, PD4, and PD7 may move to the connected floating diffusion regions FD1 to FD3 and may be accumulated. The remaining transfer transistors also operate in a similar manner, so that the charges obtained from the corresponding photodiodes PD2, PD3, PD5, PD6, PD8, and PD9 may move to the connected floating diffusion regions FD1 to FD3 and may be accumulated.

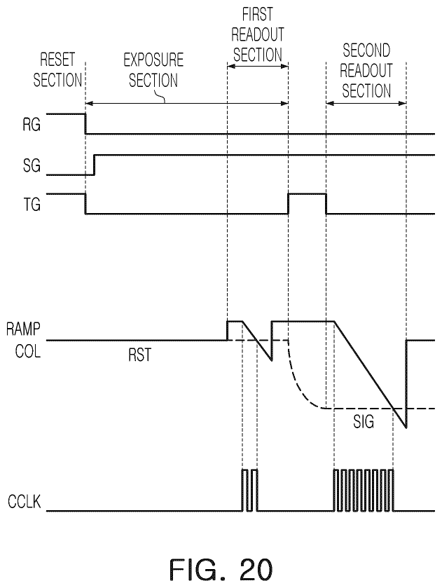

FIG. 20 is a timing diagram of a readout operation of a sub-pixel group according to some example embodiments of the present disclosure. FIG. 20 is a timing diagram for the readout operation of the sub-pixel group SPG1 to SPG3 described with reference to FIG. 19.

Referring to FIG. 20, a reset operation in which the reset transistor and the N² transfer transistors are turned on to remove, or otherwise, reduce, charges from the floating diffusion region and the N² photodiodes may be performed. Then, the reset transistor and the N² transfer transistors may be turned off to start an exposure section. During the exposure section, the pixel PX′ may be exposed to light. The photodiodes included in the pixel PX′ receiving the light may generate and accumulate charges in proportion to the incident light. The pixel PX′ may output the reset voltage RST of the floating diffusion region to the column line COL.

In the first readout section, the comparator may compare the reset voltage RST output by the pixel PX′ to the column line COL with the voltage of the ramp signal RAMP. In some example embodiments illustrated in FIG. 20, the counter may count the time during which the reset voltage RST is lower than the voltage of the ramp signal RAMP. The reset count value obtained by counting the reset voltage RST may be stored in a memory of a latch or a buffer circuit inside the counter.

Prior to the second readout operation, the transfer signal may transition to a voltage corresponding to logic high. The transfer transistors may be turned on by the transfer signals, so that the charges of the photodiodes connected to the turned-on transfer transistors may move to the floating diffusion region. The pixel PX′ may output a signal voltage SIG corresponding to the charges accumulated in the floating diffusion region to the column line COL.

In the second readout section, the comparator may compare the signal voltage SIG output by the pixel PX to the column line COL with the voltage of the ramp signal RAMP. In some example embodiments illustrated in FIG. 20, the counter may count the time during which the signal voltage SIG is lower than the voltage of the ramp signal RAMP. The signal count value obtained by counting the signal voltage SIG may be stored in a memory of a latch or a buffer circuit inside the counter. The peripheral circuit may generate a column image signal based on the reset count value and the signal count value.

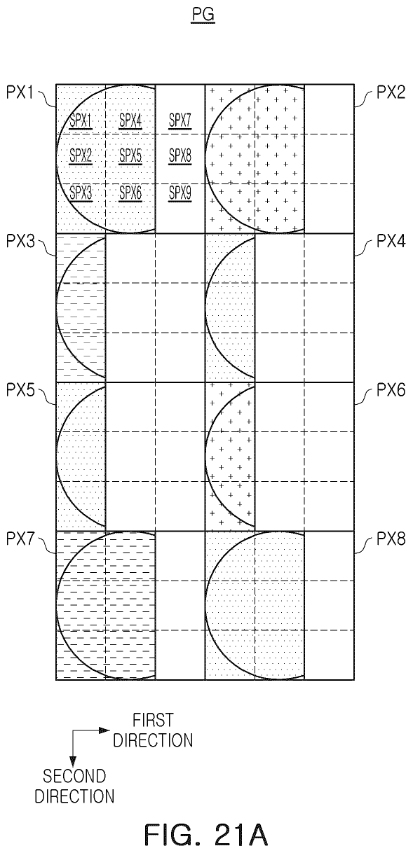

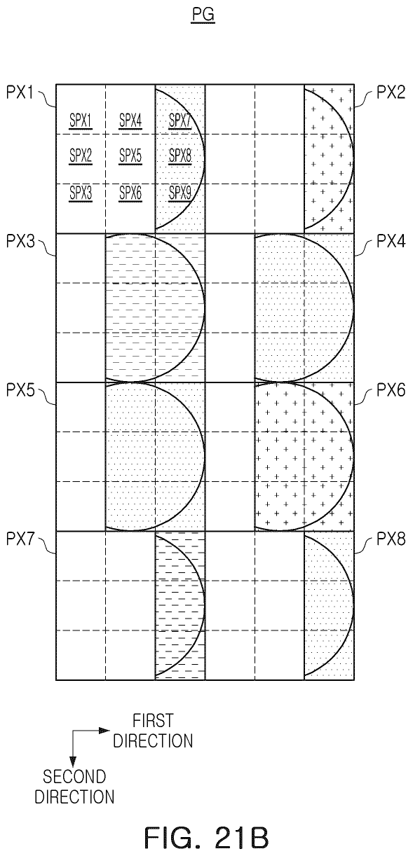

FIGS. 21A and 21B are plan views of an image signal according to some example embodiments of the present disclosure. FIGS. 21A and 21B illustrate an operation of one pixel group in a pixel array included in an image sensor according to some example embodiments of the present disclosure. In some example embodiments described with reference to FIGS. 21A and 21B, one pixel group PG may include eight pixels PX1 to PX8 disposed in a 4×2 form. In some example embodiments, each of the pixels PX1 to PX8 may include nine pixel regions SPX1 to SPX9 sharing one microlens, and each of the nine pixel regions SPX1 to SPX9 may include at least one photodiode.

FIG. 21A illustrates pixel regions in which charges corresponding to a left image signal are generated in one pixel group PG. Referring to FIG. 21A, the left image signal may correspond to charges generated in pixel regions SPX1 to SPX3 included in the first to eighth pixels PX1 to PX8 of a first column image signal, and charges generated in pixel regions SPX4 to SPX6 included in the first pixel PX1, the second pixel PX2, the seventh pixel PX7 and the eighth pixel PX8 of the second column pixel signal. In some example embodiments, the left image signal may correspond to the charges generated in the first to sixth pixel regions SPX1 to SPX6 included in each of the first pixel PX1, the second pixel PX2, the seventh pixel PX7 and the eighth pixel PX8, and the charges generated in the first to third pixel regions SPX1 to SPX3 included in each of the third to sixth pixels PX3 to PX6. The pixel regions generating the charge corresponding to the left image signal may be defined as the pixel regions of a first group, among the 72 pixel regions included in the pixel group PG.

FIG. 21B illustrates pixel regions in which the charges corresponding to the right image signal are generated in one pixel group PG. Referring to FIG. 21B, the right image signal may correspond to charges generated in pixel regions SPX4 to SPX6 included in the third to sixth pixels PX3 to PX6 of the second column image signal, and charges generated in pixel regions SPX7 to SPX9 included in the first to eighth pixels PX1 to PX8 of the third column pixel signal. In some example embodiments, the right image signal may correspond to charges generated in the seventh to ninth pixel regions SPX7 to SPX9 respectively included in the first pixel PX1, the second pixel PX2, the seventh pixel PX7 and the eighth pixel PX8, and charges generated in the fourth to ninth pixel regions SPX4 to SPX9 respectively included in the third to sixth pixels PX3 to PX6. The pixel regions generating charges corresponding to the right image signal may be defined as pixel regions of a second group, among 72 pixel regions included in the pixel group PG. In some example embodiments illustrated in FIGS. 21A and 21B, the number of pixel regions of the first group is equal to the number of pixel regions of the second group, and may be 36.

In some example embodiments of the present disclosure, the left image signal and the right image signal required to implement the autofocus function may be obtained using the first to third column image signals. The peripheral circuit or the image signal processor may drive the pixel group PG as a unit and may calculate an average value of the left image signal and an average value of the right image signal. Referring to FIGS. 21A-21B, within one pixel group PG, the number of pixel regions generating charges corresponding to the left image signal by color may be equal to the number of pixel regions generating charges corresponding to the right image signal by color. For example, nine pixel regions may be included for each of the red pixels PX2 and PX6 and the blue pixels PX3 and PX7. In some example embodiments, 18 pixel regions may be included for each of the green pixels PX1, PX4, PX5, and PX8.

The peripheral circuit or the image signal processor may obtain a phase signal pair corresponding to phase information on the object based on the average value of the left image signal and the average value of the right image signal. The image signal processor may calculate a disparity for the object using the phase signal pair. For example, two phase signals output from the same object may have different coordinates, and the disparity corresponding to the difference in the coordinates may be calculated.

The image signal processor may generate a control signal for implementing an autofocus function based on the calculated disparity. In some example embodiments, the lens driver may adjust a position of at least one of the lenses included in the lens unit based on the control signal to may adjust the focus on the object. According to some example embodiments, the processor may control the lens driver in response to the received control signal to adjust the focus on the object. In this manner, the PDAF operation may be performed using pixels including an odd number of pixel regions. Through this, angles of light incident on the pixel array may be identified with a relatively higher precision while maintaining a relatively higher resolution, thereby improving the autofocus function.

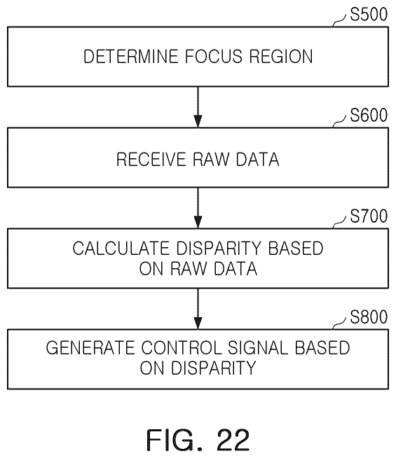

FIGS. 22 to 24 are flowcharts of the operation of an image sensor according to some example embodiments of the present disclosure. FIGS. 22 to 24 are flowcharts illustrating example operations when a pixel according to some example embodiments of the present disclosure is a pixel described with reference to FIG. 19. It is understood that additional operations can be provided before, during, and after the operations in FIG. 2, and some of the operations described below can be replaced or eliminated, for additional embodiments of the method. The order of the operations/processes may be interchangeable, or two or more operations can be performed simultaneously. The operations of the flowchart in FIG. 22 may be same as or similar in some respects to the operation of the image sensor described with reference to FIG. 11 above, and therefore may be best understood with reference thereto.

The image signal processor may determine a partial region of the entire region of an image being captured as a focus region (S500). The image signal processor may receive raw data output from a pixel array (S600). For example, the raw data may include a reset image signal and a column image signal. The image signal processor may calculate a disparity for an object based on the raw data (S700). The image signal processor may generate a control signal based on the disparity (S800). The control signal may be a signal for adjusting focus from the object.

In some example embodiments, the lens driver may adjust the distance between the lens unit and the object based on the control signal. According to some example embodiments, the processor may control the lens driver to adjust the position of the lens unit 110 based on the control signal to adjust a distance between the lens unit and the object.

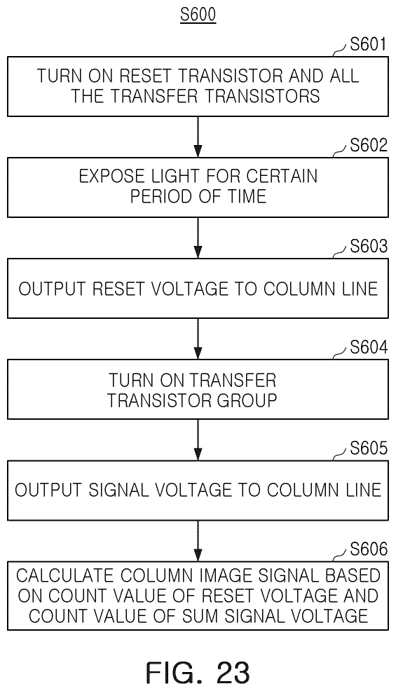

FIG. 23 illustrates operation S600 among the operation stages described with reference to FIG. 22.

The reset transistors RX1-RX3 and the N² transfer transistors may be turned on (S601), and a reset operation may be performed in which charges of the floating diffusion region FD and the N² photodiodes are removed, or otherwise, reduced. Then, the reset transistors and the N² transfer transistors may be turned off to start an exposure section. During the exposure section, light may be exposed to the pixel (S602). The N² photodiodes included in the pixel receiving the light may generate and accumulate charges in proportion to the incident light. The pixel may output the reset voltage of the floating diffusion region FD to the column line (S603).

In the first readout section, the comparator may compare the reset voltage output by the pixel to the column line with the voltage of the ramp signal. A reset count value obtained by counting the reset voltage may be stored in a memory of a latch or a buffer circuit inside the counter.

Prior to the second readout operation, the transfer signal TG1-TG3 may transition to a voltage corresponding to logic high. The transfer transistors (e.g., N² transfer transistors) are turned on by the transfer signal (S604), so that the charges of the photodiodes (e.g., PD1-PD9) connected to the turned-on transfer transistors may move to the floating diffusion region FD. The pixel may output a signal voltage corresponding to the charges accumulated in the floating diffusion region FD to the column line (S605).

In the second readout section, the comparator may compare the signal voltage output by the pixel to the column line with the voltage of the ramp signal. The signal count value obtained by counting the signal voltage may be stored in a memory of a latch or a buffer circuit inside the counter. The peripheral circuit 211 may generate a column image signal based on the reset count value and the signal count value (S606).

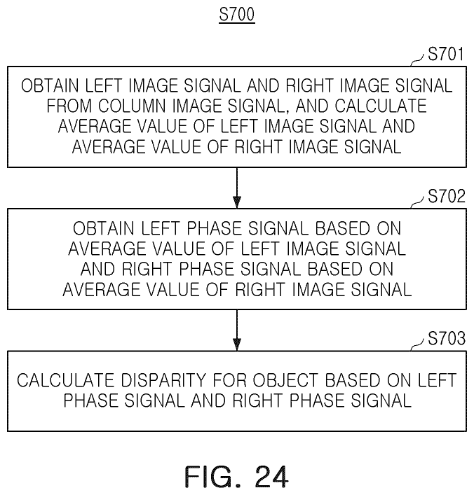

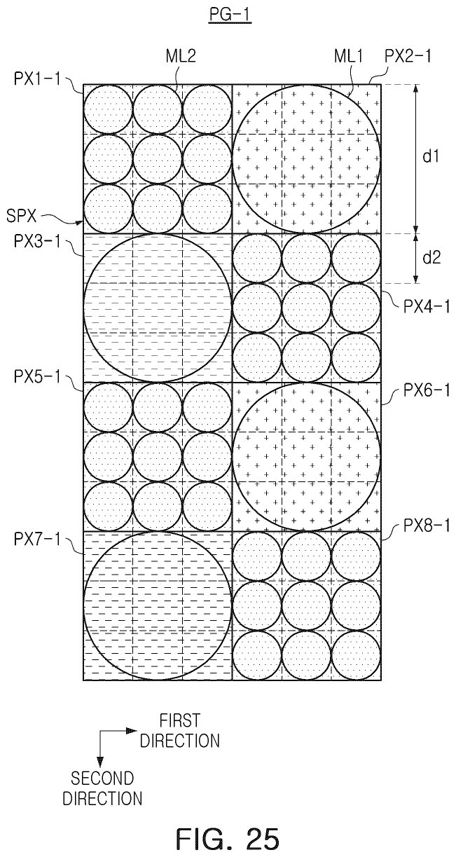

FIG. 24 illustrates operation S700 among the operation stages described with reference to FIG. 22. FIG. 24 is a flowchart of operation S600 of FIG. 22 is performed as described with reference to FIG. 23.

The peripheral circuit 211 or the image signal processor 220 may obtain the left image signal and the right image signal from the column image signal, and may calculate an average value of the left image signal and an average value of the right image signal (S701). The number of pixel regions of the first group may be equal to the number of pixel regions of the second group, and may be 36. Referring to FIGS. 21A and 21B, within one pixel group PG, the number of pixel regions generating charges corresponding to the left image signal by color may be equal to the number of pixel regions generating charges corresponding to the right image signal by color. In some example embodiments, nine pixel regions may be included for each red pixel PX2 and PX6 and each blue pixel PX3 and PX7. In some example embodiments, 18 pixel regions may be included for each green pixel PX1, PX4, PX5, and PX8.

The peripheral circuit 211 or the image signal processor 220 may obtain a phase signal pair corresponding to phase information on the object based on the average value of the left image signal and the average value of the right image signal (S702). A disparity for the object may be calculated based on the left phase signal and the right phase signal (S703). For example, two phase signals output from the same object may have different coordinates, and the disparity corresponding to the difference in the coordinates may be calculated.

The peripheral circuit 211 or the image signal processor 220 may generate a control signal for implementing an autofocus function based on the calculated disparity. In some example embodiments, the lens driver may adjust a position of at least one of the lenses included in the lens unit based on the control signal to adjust the focus for the object. According to some example embodiments, the processor may control the lens driver in response to the received control signal to adjust the focus for the object. In this manner, the PDAF operation may be performed using pixels including an odd number of pixel regions. Through this, the autofocus function may be improved by further identifying the angles of the light incident on the pixel array while maintaining a high resolution.

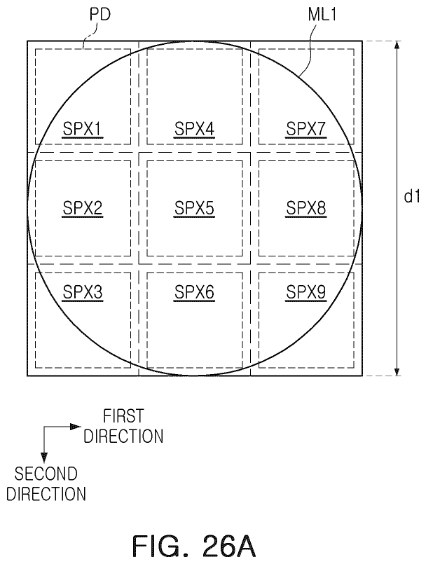

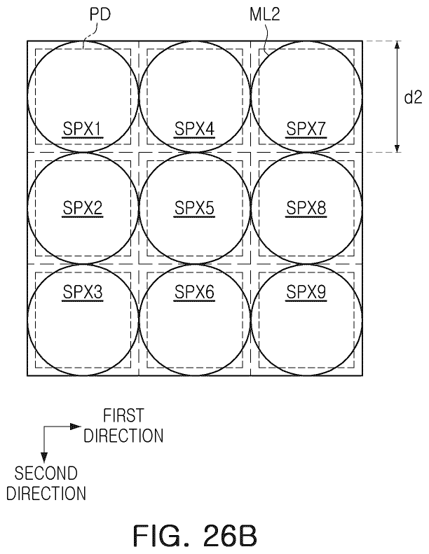

FIG. 25, FIG. 26A, and FIG. 26B are plan views of a structure of a pixel group according to some example embodiments of the present disclosure.

Referring to FIG. 25, a pixel group PG-1 according to some example embodiments of the present disclosure may include eight pixels PX1-1 to PX8-1 arranged in a 4×2 form (or matrix). Among the pixels PX1-1 to PX8-1, a first color pixel may include a first microlens ML1 having a first diameter d1 and a plurality of pixel regions SPX arranged in N×N form (where N is an odd number of 3 or more), and a second color pixel different from the first color pixel may include a plurality of second microlenses ML2 having a second diameter d2 smaller than the first diameter d1 and a plurality of pixel regions SPX arranged in NxN form. A photodiode may be disposed in each of the plurality of pixel regions SPX, and therefore, the number of photodiodes included in each of the pixels PX1-1 to PX8-1 may be greater than the number of the plurality of pixel regions SPX. In some example embodiments, each of the pixels PX1-1 to PX8-1 may include N² photodiodes arranged in NxN form. FIG. 25 illustrates that each of the pixels PX1-1 to PX8-1 includes a plurality of pixel regions SPX arranged in a 3×3 form, but the present disclosure is not limited thereto.

FIG. 26A is a plan view illustrating a first color pixel according to some example embodiments of the present disclosure. Referring to FIG. 26A, one color pixel may include a plurality of pixel regions SPX1 to SPX9 arranged in a 3×3 form, and the plurality of pixel regions SPX1 to SPX9 may share a first microlens ML1. Each of the pixel regions SPX1 to SPX9 may include a photodiode PD. The pixel regions SPX1 to SPX9 included in one pixel may share at least one or more floating diffusion regions.

FIG. 26B is a plan view illustrating a second color pixel according to some example embodiments of the present disclosure. Referring to FIG. 26B, one color pixel may include a plurality of pixel regions SPX1 to SPX9 arranged in a 3×3 configuration, and each of the pixel regions SPX1 to SPX9 may share a second microlens ML2. Each of the pixel regions SPX1 to SPX9 may include a photodiode PD. The pixel regions SPX1 to SPX9 included in one pixel may share at least one or more floating diffusion regions.

In some example embodiments, the pixel regions SPX1 to SPX9 included in the pixel may share one floating diffusion region. In some example embodiments, outputs of the pixel regions SPX1 to SPX9 included in one pixel may be output through one column line. In another example embodiment, in one pixel PX, pixel regions SPX1 to SPX3, SPX4 to SPX6 and SPX7 to SPX9 disposed in the same position in the first direction and arranged in the second direction may form a sub-pixel group sharing one floating diffusion region. In some example embodiments, pixel signals generated by charges generated by three photodiodes included in each sub-pixel group may be output through one column line.

Each of the pixel regions SPX1 to SPX9 included in the first color pixel may identify and receive light incident at different angles through the first microlens ML1. Through this, image data in which one object is viewed from different directions may be obtained. In some example embodiments, a phase signal pair may be obtained based on a pixel signal obtained from a pixel array, and a disparity may be calculated through a phase difference arithmetic operation based thereon. An AF operation may be performed on an image region corresponding to the pixel based on the calculated disparity.

Each of the pixel regions SPX1 to SPX9 included in the second color pixel may receive light incident through each of the second microlenses ML2. In some example embodiments, image data having a higher resolution may be obtained as compared to the case in which image data is output using the first color pixel.

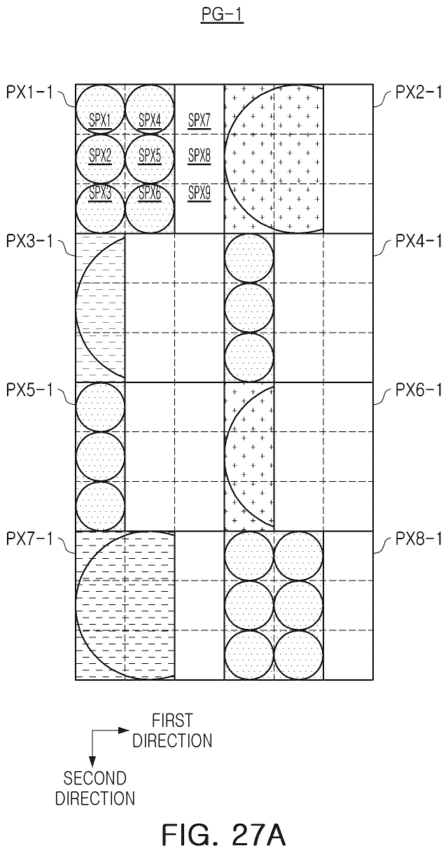

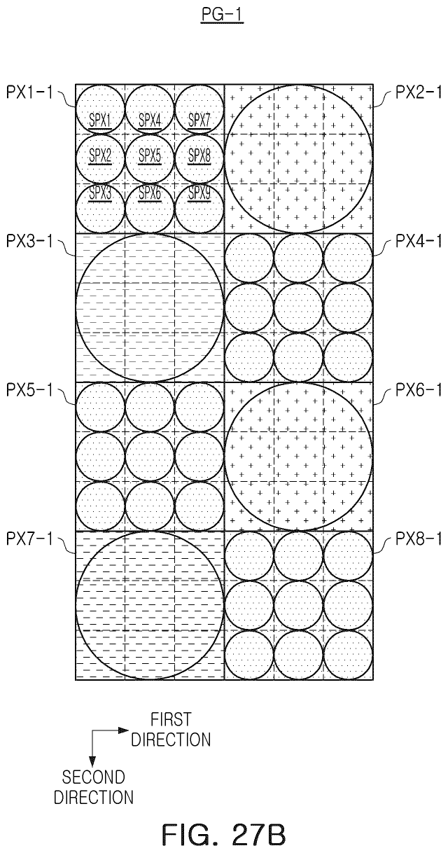

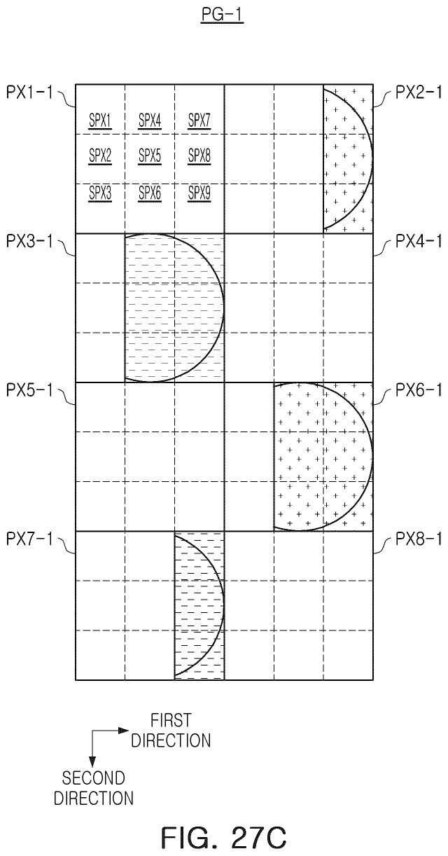

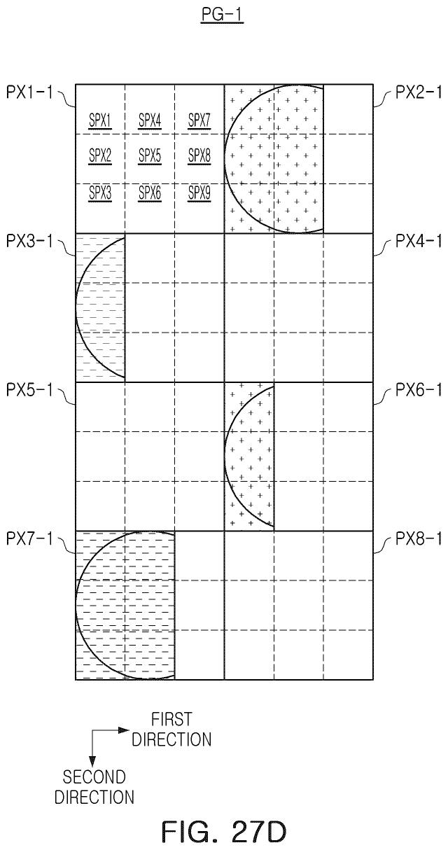

FIGS. 27A to 27D are plan views of an operation of a pixel group according to some example embodiments of the present disclosure. For convenience of explanation, FIGS. 27A to 27D assumes and illustrates the case in which the PDAF operation is performed through the RSS readout operation as described with reference to FIGS. 6 to 13, but the present disclosure is not limited thereto, and the PDAF operation may be performed through other operations such as the RSRS readout operation.

Referring to FIGS. 27A to 27D, a pixel group PG-1 according to some example embodiments of the present disclosure may include eight pixels PX1-1 to PX8-1 disposed in a 4×2 form. In some example embodiments, each of the pixels PX1-1 to PX8-1 included in the pixel group PG-1 may include a plurality of pixel regions SPX arranged in a 3×3 form, and a first color pixel may include red pixels PX2-1 and PX6-1 and blue pixels PX3-1 and PX7-1, and a second color pixel may include green pixels PX1-1, PX4-1, PX5-1 and PX8-1. However, the configuration of the pixels PX1-1 to PX8-1 and the pixel regions SPX, and the types of pixels included in the first color pixel and the second color pixel are not limited thereto.

FIG. 27A illustrates pixel regions in which charges corresponding to the first image signal are generated in one pixel group PG-1. The first image signal may correspond to charges generated by the first color pixel and the pixels arranged in the first direction of the first color pixel among the pixels PX1-1 to PX8-1. For example, referring to FIG. 27A, the first image signal may correspond to charges generated by the first to sixth pixel regions SPX1 to SPX6 included in each of the first pixel PX1-1, the second pixel PX2-1, the seventh pixel PX7-1, and the eighth pixel PX8-1, and charges generated by the first to third pixel regions SPX1 to SPX3 included in each of the third to sixth pixels PX3-1 to PX6-1.

FIG. 27B illustrates pixel regions in which charges corresponding to the sum image signal are generated in one pixel group PG-1. Referring to FIG. 27B, the sum image signal may correspond to the charges generated in each pixel region SPX1 to SPX9 of all pixels PX1-1 to PX8-1 included in the pixel group PG-1.

FIG. 27C illustrates pixel regions included in a first color filter, among pixel regions in which charges corresponding to a second image signal are generated in one pixel group PG-1. The pixel regions may be the seventh to ninth pixel regions SPX7 to SPX9 included in each of the second pixel PX2-1 and the seventh pixel PX7-1, and the fourth to ninth pixel regions SPX4 to SPX9 included in each of the third and sixth pixels PX3-1 and PX6-1. The pixel regions may be defined as pixel regions of the second group, among 72 pixel regions included in the pixel group PG-1.

FIG. 27D illustrates pixel regions included in a first color filter, among pixel regions in which charges corresponding to the first image signal are generated in one pixel group PG-1. The pixel regions may be first to sixth pixel regions SPX1 to SPX6 included in each of the second pixel PX2-1 and the seventh pixel PX7-1, and first to third pixel regions SPX1 to SPX3 included in each of the third and sixth pixels PX3-1 and PX6-1. The pixel regions may be defined as pixel regions of the first group among 72 pixel regions included in the pixel group PG-1.

A left image signal and a right image signal may be obtained from the first image signal and the second image signal. For example, referring to FIGS. 27A to 27D, the left image signal may correspond to charges generated in the first to sixth pixel regions SPX1 to SPX6 included in the second pixel PX2-1 and the seventh pixel PX7-1, respectively, and charges generated in the first to third pixel regions SPX1 to SPX3 included in the third and sixth pixels PX3-1 and PX6-1, respectively. The right image signal may correspond to charges generated in the seventh to ninth pixel regions SPX7 to SPX9 included in the second pixel PX2-1 and the seventh pixel PX7-1, respectively, and charges generated in the fourth to ninth pixel regions SPX4 to SPX9 included in the third and sixth pixels PX3-1 and PX6-1, respectively.

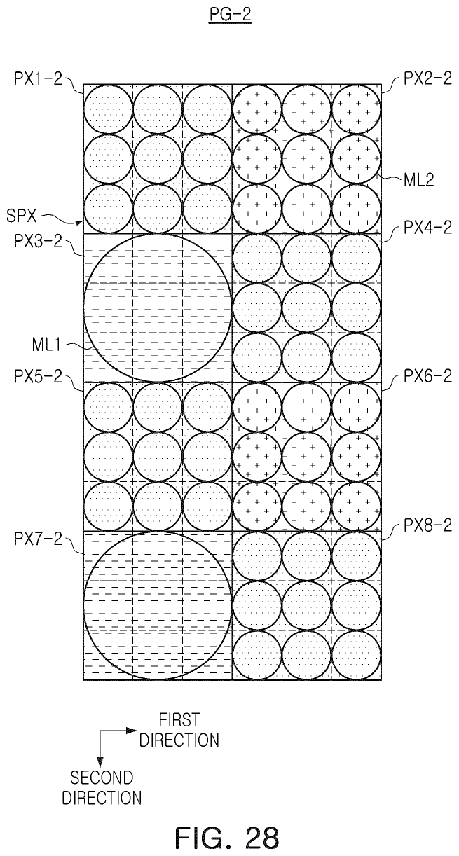

FIG. 28 is a view of an operation of a pixel group according to some example embodiments of the present disclosure. For convenience of explanation, FIG. 28 can be described as a case assuming that the PDAF operation is performed through the RSS readout operation as described with reference to FIGS. 6 to 13, but the present disclosure is not limited thereto, and the PDAF operation may be performed through other operations such as the RSRS readout operation.

Referring to FIG. 28, a pixel group PG-2 according to some example embodiments of the present disclosure may include eight pixels PX1-2 to PX8-2 arranged in a 4×2 form. In some example embodiments, each of the pixels PX1-2 to PX8-2 included in the pixel group PG-2 may include a plurality of pixel regions SPX arranged in a 3×3 form, and the first color pixel may include blue pixels PX3-2 and PX7-2, and the second color pixel may include red pixels PX2-2 and PX6-2 and green pixels PX1-2, PX4-2, PX5-2 and PX8-2. However, the configuration of pixels PX1-2 to PX8-2 and pixel regions SPX, and the types of pixels included in the first color pixel and the second color pixel are not limited thereto.

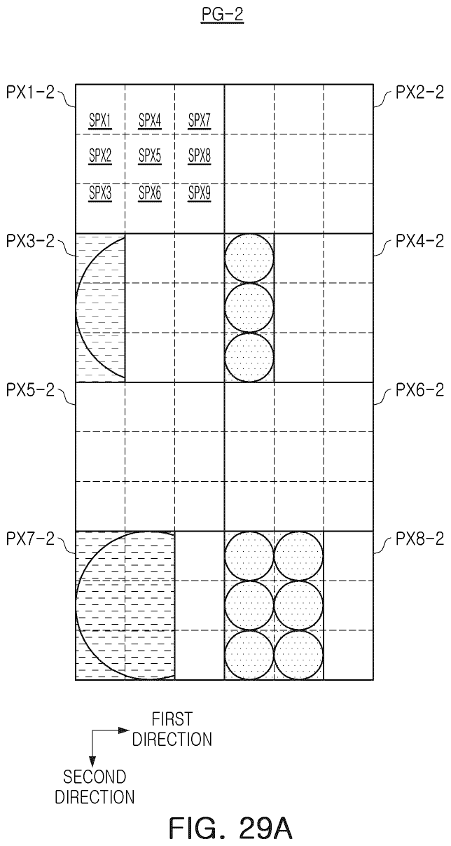

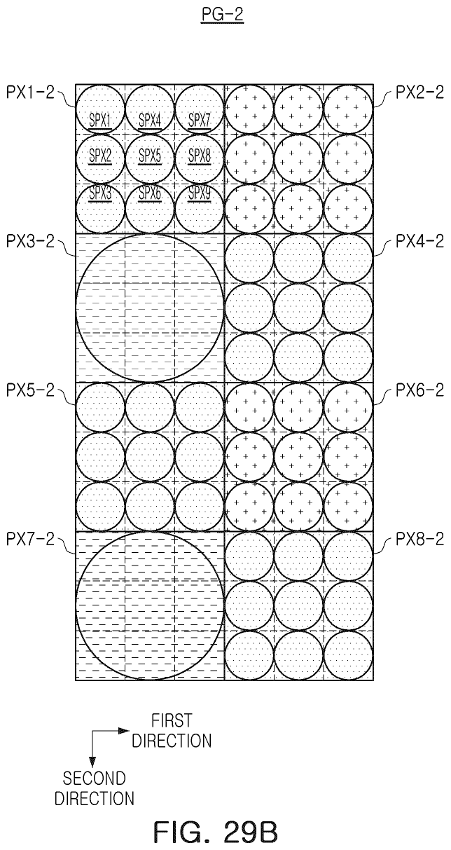

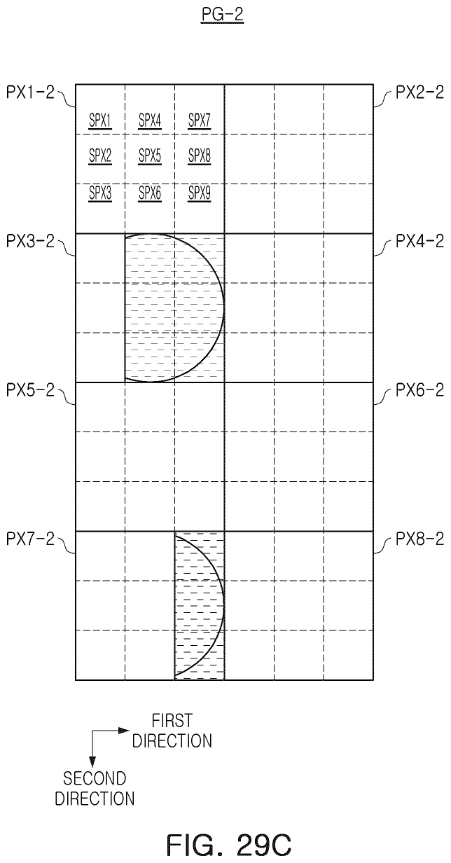

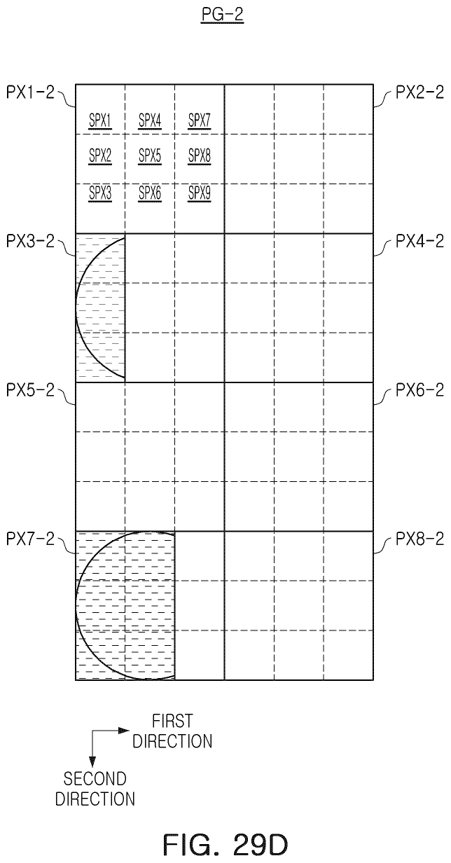

FIGS. 29A to 29D are plan views of an operation of a pixel group according to some example embodiments of the present disclosure.

FIG. 29A illustrates pixel regions in which charges corresponding to a first image signal are generated in one pixel group PG-2. The first image signal may correspond to charges generated by a first color pixel and pixels arranged in a first direction of the first color pixel, among the pixels PX1-2 to PX8-2. For example, referring to FIG. 29A, the first image signal may correspond to charges generated in the first to sixth pixel regions SPX1 to SPX6 included in each of the seventh pixel PX7-2 and the eighth pixel PX8-2, and to charges generated in the first to third pixel regions SPX1 to SPX3 included in each of the third and fourth pixels PX3-2 and PX4-2.

FIG. 29B illustrates pixel regions in which charges corresponding to the sum image signal are generated in one pixel group PG-2. Referring to FIG. 29B, the sum image signal may correspond to charges generated in the pixel regions SPX1 to SPX9 of each of all pixels PX1-2 to PX8-2 included in the pixel group PG-2.

FIG. 29C illustrates pixel regions included in a first color filter, among pixel regions in which charges corresponding to a second image signal are generated in one pixel group PG-2. The pixel regions may be the seventh to ninth pixel regions SPX7 to SPX9 included in the seventh pixel PX7-2 and the fourth to ninth pixel regions SPX4 to SPX9 included in the third pixels PX3-2. The pixel regions may be defined as pixel regions of a second group, among 72 pixel regions included in the pixel group PG-2.

FIG. 29D illustrates pixel regions included in a first color filter, among pixel regions in which charges corresponding to a first image signal are generated in one pixel group PG-2. The pixel regions may be the first to sixth pixel regions SPX1 to SPX6 included in the seventh pixel PX7-2 and the first to third pixel regions SPX1 to SPX3 included in the third pixels PX3-2. The pixel regions may be defined as pixel regions of a first group, among the 72 pixel regions included in the pixel group PG-2.

The left image signal and the right image signal may be obtained from the first image signal and the second image signal. For example, referring to FIGS. 29A to 29D, the left image signal may correspond to charges generated in the first to sixth pixel regions SPX1 to SPX6 included in the seventh pixel PX7-2 and the first to third pixel regions SPX1 to SPX3 included in the third pixels PX3-2. The right image signal may correspond to charges generated in the seventh to ninth pixel regions SPX7 to SPX9 included in the seventh pixel PX7-2, and charges generated in the fourth to ninth pixel regions SPX4 to SPX9 included in the third pixels PX3-2.

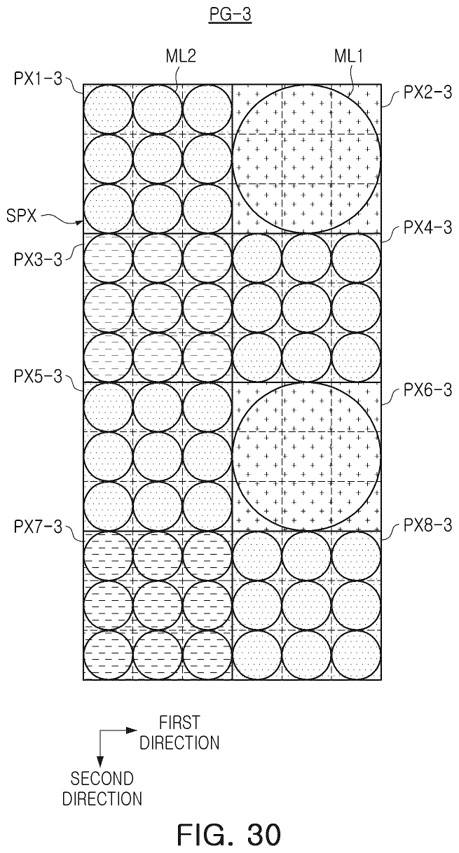

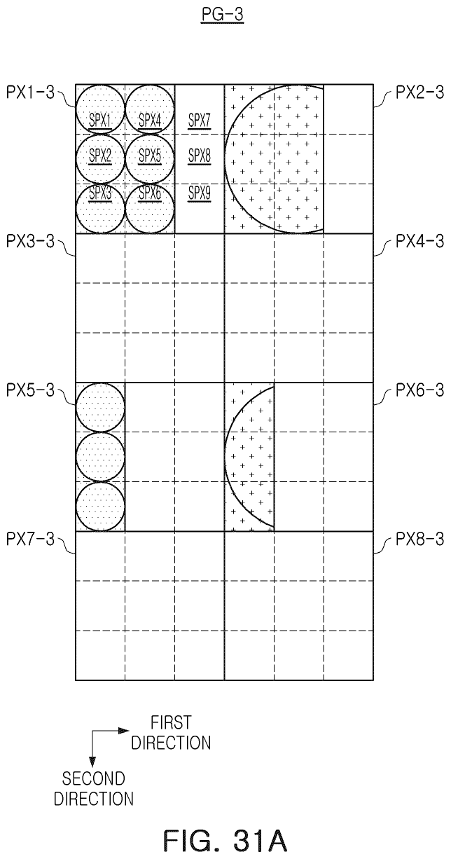

FIG. 30 is a view of the operation of a pixel group according to some example embodiments of the present disclosure. For convenience of explanation, FIG. 30 can be described as a case assuming that the PDAF operation is performed through the RSS readout operation as described with reference to FIGS. 6 to 13, but the present disclosure is not limited thereto, and the PDAF operation may be performed through other operations such as the RSRS readout operation.

Referring to FIG. 30, a pixel group PG-3 according to some example embodiments of the present disclosure may include eight pixels PX1-3 to PX8-3 arranged in a 4×2 form. In some example embodiments, each of the pixels PX1-3 to PX8-3 included in the pixel group PG-3 may include a plurality of pixel regions SPX arranged in a 3×3 form, and the first color pixel may include red pixels PX2-3 and PX6-3 and the second color pixel may include blue pixels PX3-3 and PX7-3 and green pixels PX1-3, PX4-3, PX5-3 and PX8-3. However, the configuration of the pixels PX1-3 to PX8-3 and the pixel regions SPX, and the types of pixels included in the first color pixel and the second color pixel are not limited thereto.

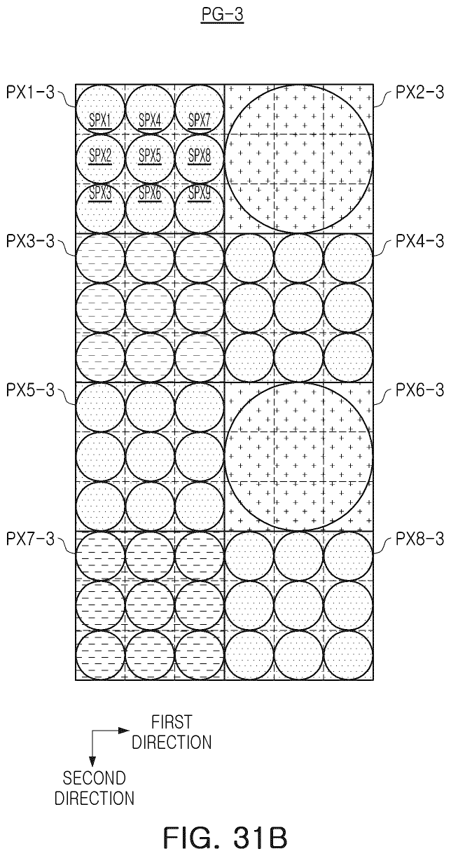

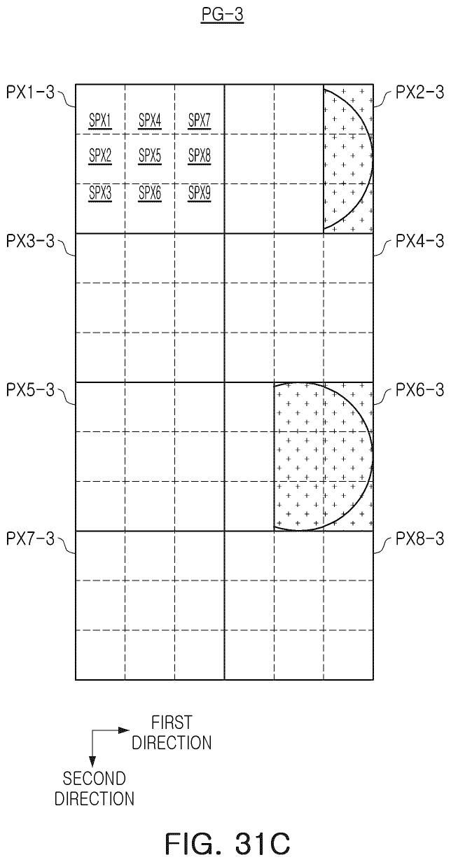

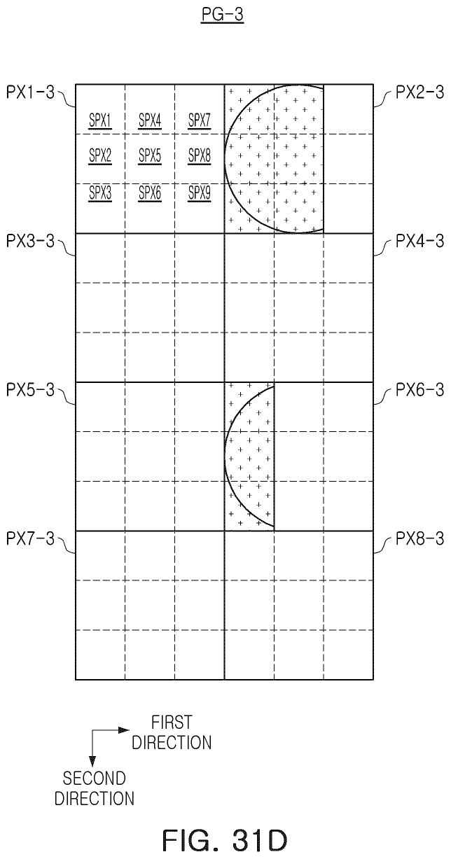

FIGS. 31A to 31D are plan views of an operation of a pixel group according to some example embodiments of the present disclosure.

FIG. 31A illustrates pixel regions in which charges corresponding to a first image signal are generated in one pixel group PG-3. The first image signal may correspond to charges generated by a first color pixel, for example a red color pixel PX1-3 and PX5-3, and a pixel arranged in a first direction of the first color pixel, for example a green color pixel PX2-3 and PX6-3, among the pixels PX1-3 to PX8-3. For example, referring to FIG. 31A, the first image signal may correspond to charges generated in the first to sixth pixel regions SPX1 to SPX6 included in each of the first pixel PX7-3 and the second pixel PX8-3, and charges generated in the first to third pixel regions SPX1 to SPX3 included in each of the fifth and sixth pixels PX5-3 and PX6-3.

FIG. 31B illustrates pixel regions in which charges corresponding to a sum image signal are generated in one pixel group PG-3. Referring to FIG. 31B, the sum image signal may correspond to charges generated in each pixel region SPX1 to SPX9 of all pixels PX1-3 to PX8-3 included in the pixel group PG-3.

FIG. 31C illustrates pixel regions included in the first color filter, among pixel regions in which charges corresponding to the second image signal are generated in one pixel group PG-3. The pixel regions may be the seventh to ninth pixel regions SPX7 to SPX9 included in the second pixel PX2-3 and may be the fourth to ninth pixel regions SPX4 to SPX9 included in the sixth pixels PX6-3. The pixel regions may be defined as pixel regions of the second group, among the 72 pixel regions included in the pixel group PG-3.

FIG. 31D illustrates pixel regions included in a first color filter, among pixel regions in which charges corresponding to the first image signal are generated in one pixel group PG-3. The pixel regions may be the first to sixth pixel regions SPX1 to SPX6 included in the second pixel PX2-3 and may be the first to third pixel regions SPX1 to SPX3 included in the sixth pixels PX6-3. The pixel regions may be defined as pixel regions of the first group among the 72 pixel regions included in the pixel group PG-3.

A left image signal and a right image signal may be obtained from the first image signal and the second image signal. For example, referring to FIGS. 21A to 31D, the left image signal may correspond to charges generated in the first to sixth pixel regions SPX1 to SPX6 included in the second pixel PX2-3 and charges generated in the first to third pixel regions SPX1 to SPX3 included in the sixth pixels PX6-3. The right image signal may correspond to charges generated in the seventh to ninth pixel regions SPX7 to SPX9 included in the second pixel PX2-3 and charges generated in the fourth to ninth pixel regions SPX4 to SPX9 included in the sixth pixels PX6-3.

The peripheral circuit 211 or the image signal processor 220 may obtain the left image signal and the right image signal from the column image signal, and may calculate an average value of the left image signal and an average value of the right image signal. The number of pixel regions of the first group may be equal to the number of pixel regions of the second group. Within one pixel group PG, the number of pixel regions generating charges corresponding to the left image signal by color may be equal to the number of pixel regions generating charges corresponding to the right image signal by color.

The peripheral circuit 211 or the image signal processor 220 may obtain a phase signal pair corresponding to phase information on the object based on the average value of the left image signal and the average value of the right image signal. A disparity for the object may be calculated based on the left phase signal and the right phase signal. For example, two phase signals output from the same object may have different coordinates, and the disparity corresponding to a difference in the coordinates may be calculated.

The peripheral circuit 211 or the image signal processor 220 may generate a control signal for implementing an autofocus function based on the calculated disparity. In some example embodiments, the lens driver may adjust a position of at least one of the lenses included in the lens unit based on the control signal to adjust the focus for the object. According to some example embodiments, the processor may control the lens driver in response to the received control signal to adjust the focus for the object. In this manner, the PDAF operation may be performed using pixels including an odd number of pixel regions. Through this, angles of light incident on the pixel array may be identified with a relatively higher precision while maintaining a relatively higher resolution, thereby improving the autofocus function. In some example embodiments, the pixel array may be arranged with the first color pixels and the second color pixels together, so that image data having a higher resolution may be obtained as compared to the case in which only the first color pixels are arranged.

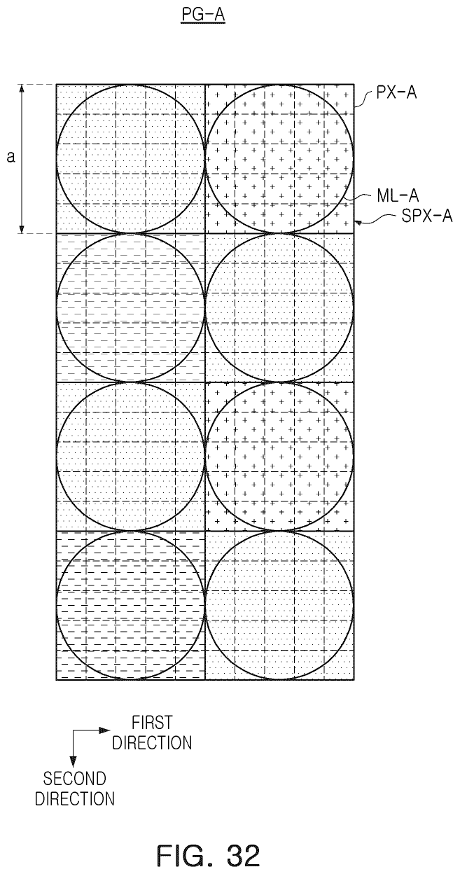

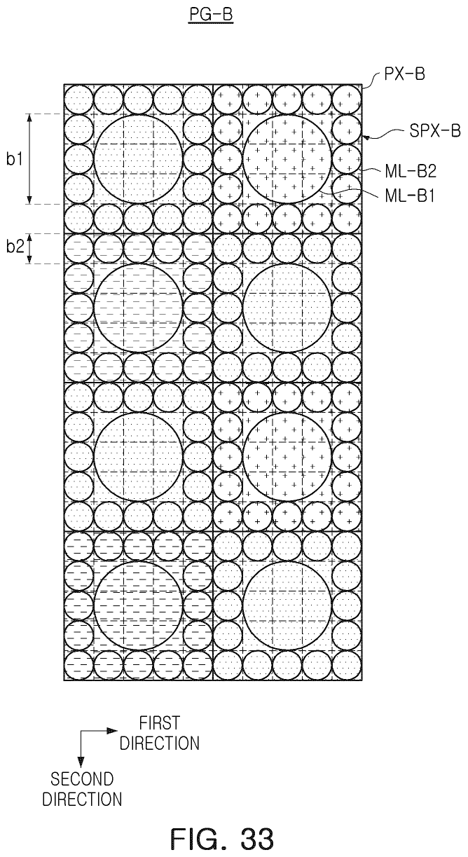

FIG. 32 and FIG. 33 are plan views of a structure of a pixel group according to some example embodiments of the present disclosure.

Referring to FIG. 32, a pixel group PG-A according to some example embodiments of the present disclosure may include eight pixels PX-A arranged in a 4×2 form. Each of the pixels PX-A may include a plurality of pixel regions SPX-A arranged in a 5×5 form, and a first microlens ML-A having a first diameter (a) may be disposed on each of the pixel regions SPX-A. The first microlens ML-A may be disposed so as to be shared between pixel regions SPX-A included in one pixel PX-A.

Each of the pixel regions SPX-A included in the pixel PX-A including the first microlens ML-A may identify and receive light incident at different angles. Through this, image data of one object viewed from different directions may be obtained. In this case, a phase signal pair may be obtained based on the pixel signal obtained from the pixel array, and a disparity may be calculated through a phase difference arithmetic operation based thereon. An AF operation may be performed on an image area corresponding to the pixel based on the calculated disparity.

Referring to FIG. 33, a pixel group PG-B according to some example embodiments of the present disclosure may include eight pixels PX-B arranged in a 4×2 form. Each pixel PX-B may include a plurality of pixel regions SPX-B arranged in a 5×5 form, and a second microlens ML-B1 having a second diameter (b1) or a third microlens ML-B2 having a third diameter (b2) smaller than the second diameter (b1) may be disposed on each pixel region SPX-B. The second microlens ML-B1 may be arranged so that some of the pixel regions SPX-B included in one pixel PX-B are shared. The third microlens ML-B2 may be arranged one by one for each pixel region SPX-B included in one pixel PX-B.

Each of the pixel regions SPX-B included in the pixel PX-B including the second microlens ML-B1 may identify and receive light incident at different angles. Through this, image data of an object viewed from different directions may be obtained. In this case, a phase signal pair may be obtained based on the pixel signal obtained from the pixel array, and a disparity may be calculated based thereon through a phase difference arithmetic operation. An AF operation may be performed on an image area corresponding to a pixel based on the calculated disparity.

Each of the pixel regions SPX-B included in the pixels PX-B including the third microlenses ML-B2 may receive light incident through each of the third microlenses ML-B2. In this case, image data with a higher resolution may be obtained as compared to the case in which only the first microlens ML-A is disposed.

As the number of pixel regions sharing the microlenses increases, a relatively higher number of angles of the incident light may be identified with a relatively higher resolution. Relatively large microlenses may be arranged. In some example embodiments, the angles of the light may be clearly identified in a periphery of the pixel array, and the autofocus function may be improved.

In the example embodiments illustrated in FIG. 3 to FIG. 33, it is illustrated under the assumption that pixels arranged in the same row operate identically, but the example embodiments are not limited thereto, and the pixels may operate differently in some example embodiments. For example, the number of transfer transistors included in the first transfer transistor group and/or the second transfer transistor group may vary. Also, it is assumed that pixel regions in the same column included in the same pixel operate in a same or similar manner, but the example embodiments are not limited thereto, and the pixel regions may operate differently in some example embodiments.

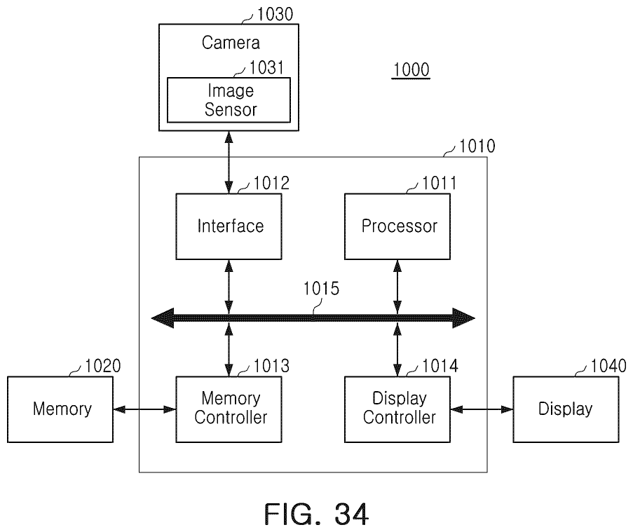

FIG. 34 is a block diagram illustrating a charge device including an imaging device according to some example embodiments of the present disclosure.

Referring to FIG. 34, a charge device 1000 according to some example embodiments of the present disclosure may include a camera 1030, a controller 1010, a memory 1020 and a display 1040.

The charge device 1000 may include a device having an image sensor 1031, such as a DSLR9 Digital Signal Lens Reflex Camera, a smartphone, a wearable device, an Internet of Things (IoT) device, a home appliance, a Personal Computer (tablet PC), Personal Digital Assistant (PDA), and Portable Multimedia Player (PMP). In some example embodiments, a device having an image sensor 1031 may also be included as a component in a vehicle, furniture, manufacturing equipment, a door, various measuring devices, and the like.

The camera 1030 may include an image sensor 1031. The image sensor 1031 may be implemented as the image sensor described above with reference to FIGS. 1 to 33. The camera 1030 may obtain a pixel signal using the image sensor 1031, and may perform pixel signal processing on the pixel signal and may output the processed pixel signal to the controller 1010.

The controller 1010 may include a processor 1011. The processor 1011 may control an overall operation of each component of the charge device 1000. The processor 1011 may be implemented as at least one of various processing units such as a Central Processing Unit (CPU), an Application Processor (AP), and a Graphics Processing Unit (GPU). In some example embodiments, the controller 1010 may be implemented as an integrated circuit or a system on chip (SoC). For example, the processor 1011 may obtain an image file from the image data received from the image sensor 1031 and may store an image file in the memory 1020, and may also restore the image data from the image file stored in the memory 1020. According to some example embodiments, the processor 1011 may perform an AF function based on phase information included in the image data received from the image sensor 1031 to adjust the focus in the up, down, left, and right directions for the object.

In some example embodiments, the controller 1010 may further include an interface 1012, a memory controller 1013, a display controller 1014, and a bus 1015. According to some example embodiments, at least some of the interface 1012, the memory controller 1013, the display controller 1014 and the bus 1015 may be provided outside (or external to) the controller 1010.

The interface 1012 may transmit a pixel signal received from the image sensor 1031 to the memory controller 1013 or the display controller 1014 through the bus 1015. The memory controller 1013 may control data transmission and reception with the memory 1020 or command transmission to the memory 1020. The memory 1020 may store various data and commands.

Based on a control from the processor 1011, the display controller 1014 may transmit data to the display 1040 to be output from the display 1040, and the display 1040 may display a screen according to the received data. In some example embodiments, the display 1040 may further include a touch screen. The touch screen may transmit a user input capable of controlling the operation of the charge device 1000 to the controller 1010. A user input may be obtained when the user touches the touch screen. For example, when a user touches a specific region of the display 1040 screen, the coordinates of the screen corresponding to the corresponding region may be transmitted to the controller 1010, and the controller 1010 may control the image sensor 1031 to focus on an image region corresponding to the corresponding coordinates.

The bus 1015 may provide a communication function between components of the controller 1010. The bus 1015 may include at least one type of bus according to a communication protocol between components.

Example embodiments are not necessarily mutually exclusive. For example, some example embodiments may include one or more features described with reference to one or more figures, and may also include one or more other features described with reference to one or more other figures.

As described herein, any devices, systems, modules, portions, units, controllers, circuits, and/or portions thereof according to any of the example embodiments, and/or any portions thereof (including, without limitation, the optical unit 100, the lens driver 120, the image sensor 200, the image signal processor 220, the processor 300, the row driver 230, the control logic 240, the readout circuit 250, the data output circuit 260, the timing controller 241, the ramp signal generator 242, the clock signal generator 243, the buffer circuit 261, the plurality of memories MEM, the charge device 1000, the camera 1030, the controller 1010, the memory 1020, the display 1040, the image sensor 1031, the interface 1012, the memory controller 1013, the display controller 1014, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. An image sensor, comprising:
a plurality of pixels including at least one first pixel;
a first microlens on the at least one first pixel; and
a peripheral circuit configured to drive the at least one first pixel,
wherein the at least one first pixel comprises a first N² photodiodes in N×N form, and a first N² transfer transistors each connected to corresponding one of the first N² photodiodes,
wherein P transfer transistors among the first N² transfer transistors are configured to be turned on at a time t1 and L transfer transistors among the first N² transfer transistors are configured to be turned on at a time t2 different from the time t1,
wherein P, N, and L are integers,
wherein N is an odd number equal to or greater than 3,
wherein P is greater than N²/2,
wherein L is equal to or greater than 2,
wherein P is different from L, and
wherein the P transfer transistors are included in a first transistor group and the L transfer transistors are included in a second transistor group different from the first transistor group.

2. The image sensor of claim 1, wherein N transfer transistors among the P transfer transistors are in a first direction.

3. The image sensor of claim 2, wherein L is equal to or greater than 3.

4. The image sensor of claim 3, wherein N transfer transistors among the L transfer transistors are in the first direction.

5. The image sensor of claim 4, wherein L+P is N².

6. The image sensor of claim 4, wherein P is equal to or greater than 2N.

7. The image sensor of claim 1, further comprising a green color filter on the at least one first pixel.

8. The image sensor of claim 1, further comprising a red color filter on the at least one first pixel.

9. The image sensor of claim 1, further comprising a blue color filter on the at least one first pixel.

10. The image sensor of claim 4, wherein the plurality of pixels further includes at least one second pixel different from the at least one first pixel,
wherein the at least one second pixel comprises a second N² photodiodes in N×N form, and a second N² transfer transistors each connected to corresponding one of the second N² photodiodes,
wherein T transfer transistors among the second N² transfer transistors are configured to be turned on at the time t1,
wherein T is integer equal to or greater than N, and
wherein T is different from P, and
wherein the at least one second pixel is directly adjacent to the at least one first pixel.

11. The image sensor of claim 10, wherein the at least one second pixel is directly adjacent to the at least one first pixel in the first direction.

12. The image sensor of claim 10, wherein the at least one second pixel is directly adjacent to the at least one first pixel in a second direction perpendicular to the first direction.

13. The image sensor of claim 11, wherein T is same as L.

14. An image sensor, comprising:
a plurality of pixels including a first pixel;
a first microlens on the first pixel; and
a peripheral circuit configured to drive the first pixel,
wherein the first pixel comprises N² photodiodes in NxN form and N² transfer transistors each connected to corresponding one of the N² photodiodes,
wherein P transfer transistors among the N² transfer transistors are configured to be turned on at a time t1 and L transfer transistors among the N² transfer transistors are configured to be turned on at a time t2 different from the time t1,
wherein P, N, and L are integers,
wherein N is an odd number equal to or greater than 3,
wherein P is different from L,
wherein the P transfer transistors are included in a first transistor group and the L transfer transistors are included in a second transistor group different from the first transistor group, and
wherein the peripheral circuit is configured to generate a first signal by turning on the P transfer transistors based on P photodiodes included in the first pixel and generate a second signal by turning on the L transfer transistors based on P+L photodiodes included in the first pixel.

15. The image sensor of claim 14, wherein N transfer transistors among the P transfer transistors are in a first direction.

16. The image sensor of claim 15, wherein L is equal to or greater than 3.

17. The image sensor of claim 16, wherein N transfer transistors among the L transfer transistors are in the first direction.

18. The image sensor of claim 17, wherein L+P is N².

19. The image sensor of claim 14, further comprising a green color filter on the first pixel.

20. An image sensor, comprising:
a plurality of pixels including a first pixel;
a first microlens on the first pixel; and
a peripheral circuit configured to drive the first pixel,
wherein the first pixel comprises N² photodiodes in N×N form and N² transfer transistors each connected to corresponding one of the N² photodiodes,
wherein P transfer transistors among the N² transfer transistors are configured to be turned on at a time t1 and L transfer transistors among the N² transfer transistors are configured to be turned on at a time t2 different from the time t1,
wherein P, N, and L are integers,
wherein N is an odd number equal to or greater than 3,
wherein P is equal to or greater than 2 L,
wherein the P transfer transistors are included in a first transistor group and the L transfer transistors are included in a second transistor group different from the first transistor group, and
wherein the peripheral circuit is configured to generate a first signal by turning on the P transfer transistors based on P photodiodes included in the first pixel and generate a second signal by turning on the L transfer transistors based on P+L photodiodes included in the first pixel.
